(19) United States
(12) Patent Application Publication
(10) Pub. No.: US 2024/0322045 A1
(43) Pub. Date: Sep. 26, 2024

(54) SEMICONDUCTOR DEVICE AND SEMICONDUCTOR STORAGE DEVICE

(71) Applicant: Kioxia Corporation, Tokyo (JP)

(72) Inventors: Takanori AKITA, Yokkaichi Mie (JP); Kotaro NODA, Yokkaichi Mie (JP); Takahiro FUJII, Nagoya Aichi (JP); Kasumi OKABE, Nagoya Aichi (JP)

(73) Assignee: Kioxia Corporation, Tokyo (JP)

(21) Appl. No.: 18/593,038

(22) Filed: Mar. 1, 2024

(30) Foreign Application Priority Data
Mar. 23, 2023 (JP) 2023-047031

(51) Int. Cl. H01L 29/786; H10B 12/00

(52) U.S. Cl. CPC H01L 29/7869; H10B 12/30; H10B 12/05; H10B 12/50

(57) ABSTRACT

A semiconductor device includes a first insulating layer; an oxide semiconductor formed in the first insulating layer, extending in a first direction, and having a first end and a second end; a first electrode including a first metal film that includes a first metal atom, and a first conductive film that is formed between the first metal film and the first end of the oxide semiconductor and includes metal oxide; a second electrode in contact with the second end of the oxide semiconductor; at least a pair of gate electrodes that face each other via an insulating film, and are interposed between the first end and the second end of the oxide semiconductor; and a first structure that is separated from the first electrode in a second direction intersecting the first direction, includes at least the first metal atom, and does not include the metal oxide.

### CROSS-REFERENCE TO RELATED APPLICATION

This application is based upon and claims the benefit of priority from Japanese Patent Application No. 2023-047031, filed Mar. 23, 2023, the entire contents of which are incorporated herein by reference.

### FIELD

Embodiments described herein relate generally to a semiconductor device and a semiconductor storage device.

### BACKGROUND

In some semiconductor elements, a metal oxide containing indium and tin is used for an electrode.

### DESCRIPTION OF THE DRAWINGS

FIG. 1 is a circuit diagram illustrating a circuit configuration example of a memory cell array according to a first embodiment.

FIG. 2 is a schematic cross-sectional view illustrating a structural example of the semiconductor storage device according to the first embodiment, and shows a cross-sectional view parallel to a ZX plane.

FIG. 3 is a schematic cross-sectional view illustrating a structural example of the semiconductor device according to the first embodiment, and shows a cross-sectional view parallel to a ZX plane.

FIG. 4 is a schematic plan view illustrating a structural example of the semiconductor device according to the first embodiment, and shows a plan view viewed from the upper side.

FIG. 5 is a schematic cross-sectional view illustrating a structural example of a first modification example of the projection portion Peri portion mark according to the first embodiment, and shows a cross-sectional view parallel to a ZX plane.

FIG. 6 is a schematic cross-sectional view illustrating a structural example of a second modification example of the projection portion Peri portion mark according to the first embodiment, and shows a cross-sectional view parallel to a ZX plane.

FIG. 7 is a schematic cross-sectional view illustrating a structural example of a third modification example of the projection portion Peri portion mark according to the first embodiment, and shows a cross-sectional view parallel to a ZX plane.

FIG. 8 is a schematic cross-sectional view illustrating a structural example of a fourth modification example of the projection portion Peri portion mark according to the first embodiment, and shows a cross-sectional view parallel to a ZX plane.

FIG. 9 is a schematic cross-sectional view illustrating a structural example of a first modification example of the dummy LP array unit according to the first embodiment, and shows a cross-sectional view parallel to a ZX plane.

FIG. 10 is a schematic cross-sectional view illustrating a structural example of a second modification example of the dummy LP array unit according to the first embodiment, and shows a cross-sectional view parallel to a ZX plane.

FIG. 11 is a schematic cross-sectional view illustrating a structural example of a third modification example of the dummy LP array unit according to the first embodiment, and shows a cross-sectional view parallel to a ZX plane.

FIG. 12 is a schematic cross-sectional view illustrating a structural example of a fourth modification example of the dummy LP array unit according to the first embodiment, and shows a cross-sectional view parallel to a ZX plane.

FIG. 13 is a schematic view showing a manufacturing process of a semiconductor device according to the first embodiment.

FIG. 14 is a schematic view showing a manufacturing process of a semiconductor device according to the first embodiment.

FIG. 15 is a schematic view showing a manufacturing process of a semiconductor device according to the first embodiment.

FIG. 16 is a schematic view showing a manufacturing process of a semiconductor device according to the first embodiment.

FIG. 17 is a schematic view showing a manufacturing process of a semiconductor device according to the first embodiment.

FIG. 18 is a schematic view showing a manufacturing process of a semiconductor device according to the first embodiment.

FIG. 19 is a schematic view showing a manufacturing process of a semiconductor device according to the first embodiment.

FIG. 20 is a schematic view showing a manufacturing process of a semiconductor device according to the first embodiment.

FIG. 21 is a schematic view showing a manufacturing process of a semiconductor device according to the first embodiment.

FIG. 22 is a schematic view showing a manufacturing process of a semiconductor device according to the first embodiment.

FIG. 23 is a schematic cross-sectional view illustrating a structural example of a semiconductor device according to a comparative example, and shows a cross-sectional view parallel to a ZX plane.

FIG. 24 is a schematic cross-sectional view illustrating a structural example of a semiconductor device according to the second embodiment, and shows a cross-sectional view parallel to the YZ plane of the semiconductor device of the first example of the second embodiment.

FIG. 25 is a schematic view showing a manufacturing process of a semiconductor device according to the first example of the second embodiment.

FIG. 26 is a schematic view showing a manufacturing process of a semiconductor device according to the first example of the second embodiment.

FIG. 27 is a schematic view showing a manufacturing process of a semiconductor device according to the first example of the second embodiment.

FIG. 28 is a schematic view showing a manufacturing process of a semiconductor device according to the first example of the second embodiment.

FIG. 29 is a schematic view showing a manufacturing process of a semiconductor device according to the first example of the second embodiment.

FIG. 30 is a schematic view showing a manufacturing process of a semiconductor device according to the first example of the second embodiment.

FIG. 31 is a schematic view showing a manufacturing process of a semiconductor device according to the first example of the second embodiment.

FIG. 32 is a schematic cross-sectional view illustrating a structural example of a semiconductor device according to the second embodiment, and shows a cross-sectional view parallel to a YZ plane of the semiconductor device of the second example of the second embodiment.

FIG. 33 is a schematic cross-sectional view illustrating a structural example of a semiconductor device according to the second embodiment, and shows a cross-sectional view parallel to a YZ plane of the semiconductor device of the third example of the second embodiment.

FIG. 34 is a schematic view showing a manufacturing process of a semiconductor device according to the third example of the second embodiment.

FIG. 35 is a schematic view showing a manufacturing process of a semiconductor device according to the third example of the second embodiment.

FIG. 36 is a schematic cross-sectional view illustrating a structural example of a semiconductor device according to the second embodiment, and shows a cross-sectional view parallel to a YZ plane of the semiconductor device of the fourth example of the second embodiment.

FIG. 37 is a schematic cross-sectional view illustrating a structural example of a semiconductor device according to the second embodiment, and shows a cross-sectional view parallel to a YZ plane of the semiconductor device of the fifth example of the second embodiment.

FIG. 38 is a schematic cross-sectional view illustrating a structural example of a semiconductor device according to the second embodiment, and shows a cross-sectional view parallel to a YZ plane of the semiconductor device of the sixth example of the second embodiment.

FIG. 39 is a schematic cross-sectional view illustrating a structural example of a semiconductor device according to the second embodiment, and shows a cross-sectional view parallel to a YZ plane of the semiconductor device of the seventh example of the second embodiment.

FIG. 40 is a schematic cross-sectional view illustrating a structural example of a semiconductor device according to the second embodiment, and shows a cross-sectional view parallel to a YZ plane of the semiconductor device of the eighth example of the second embodiment.

FIG. 41 is a schematic cross-sectional view illustrating a structural example of a semiconductor device according to the second embodiment, and shows a cross-sectional view parallel to a YZ plane of the semiconductor device of the ninth example of the second embodiment.

FIG. 42 is a schematic cross-sectional view illustrating a structural example of a semiconductor device according to the second embodiment, and shows a cross-sectional view parallel to a YZ plane of the semiconductor device of the tenth example of the second embodiment.

FIG. 43 is a schematic cross-sectional view illustrating a structural example of a semiconductor device according to the second embodiment, and shows a cross-sectional view parallel to a YZ plane of the semiconductor device of the eleventh example of the second embodiment.

### DETAILED DESCRIPTION

There is a demand for a technique for manufacturing a high-quality semiconductor device in a manufacturing process of a semiconductor element in which a metal oxide is used for an electrode.

Embodiments provide a semiconductor device and a semiconductor storage device capable of manufacturing a high-quality semiconductor device.

In general, according to one embodiment, a semiconductor device includes a first insulating layer; an oxide semiconductor formed in the first insulating layer, extending in a first direction, and having a first end and a second end; a first electrode including a first metal film that includes a first metal atom, and a first conductive film that is formed between the first metal film and the first end of the oxide semiconductor and includes metal oxide; a second electrode in contact with the second end of the oxide semiconductor; at least a pair of gate electrodes that face each other via an insulating film, and are interposed between the first end and the second end of the oxide semiconductor; and a first structure that is separated from the first electrode in a second direction intersecting the first direction, includes at least the first metal atom, and does not include the metal oxide.

In general, according to one embodiment, a semiconductor device is provided with a first insulating layer, an oxide semiconductor that is formed in the first insulating layer, is provided with a first end and a second end, and extends in a first direction facing the first end from the second end, a first electrode that is formed in the first direction with respect to the oxide semiconductor, the first electrode being provided with a first portion in contact with the first end of the oxide semiconductor, and provided with a first side surface in a second direction intersecting the first direction, and a second portion provided in the first direction with respect to the first portion, and provided with a second side surface in the second direction, a second electrode that is in contact with the second end of the oxide semiconductor, gate electrodes that face each other via an insulating film between the first end and the second end of the oxide semiconductor, and a first film, in which the first portion contains indium and tin as metal elements, and is provided with at least a first metal oxide electrode portion provided in a direction opposite to the first direction, the second portion contains tungsten, and is provided with at least a pad provided in the first direction, the first side surface is located in the second direction with respect to the second side surface in a cross section parallel to a plane defined by the first direction and the second direction, and the first film covers the second side surface. In general, according to one embodiment, a semiconductor storage device is provided with the semiconductor device, a first capacitor electrode that is connected to the first electrode or the second electrode, a second capacitor electrode that faces the first capacitor electrode, and a dielectric film that is provided between the first capacitor electrode and the second capacitor electrode.

Hereinafter, the present embodiment will be described with reference to the drawings. In order to facilitate understanding of the description, the same elements are designated by the same reference numerals as much as possible in each drawing, and duplicate description is omitted.

### First Embodiment

A configuration of the semiconductor storage device according to the first embodiment will be described. Each drawing may show an X-axis, a Y-axis, and a Z-axis. The X-axis, the Y-axis, and the Z-axis form a three-dimensional right-handed orthogonal coordinate. Hereinafter, the arrow direction of the X-axis may be referred to as the X-axis+direction, and the opposite direction to the arrow may be referred to as the X-axis−direction, and the same applies to other axes. The Z-axis+direction and the Z-axis−direction may also be referred to as an “upper side” and a “lower side”, respectively. In addition, a plane orthogonal to each of the X-axis, the Y-axis, or the Z-axis may be referred to as a YZ plane, a ZX plane, or an XY plane. In addition, the Z-axis direction may be referred to as an “up-down direction”. The terms “upper side”, “lower side”, and “up-down direction” are terms indicating a relative positional relationship in the drawing, and are not terms for determining an orientation based on a vertical direction.

In the present specification, the term “connection” includes not only a physical connection but also an electrical connection, and includes not only a direct connection but also an indirect connection, unless otherwise specified.

The semiconductor storage device 101 according to the first embodiment is an oxide semiconductor-random access memory (OS-RAM) and is provided with a memory cell array.

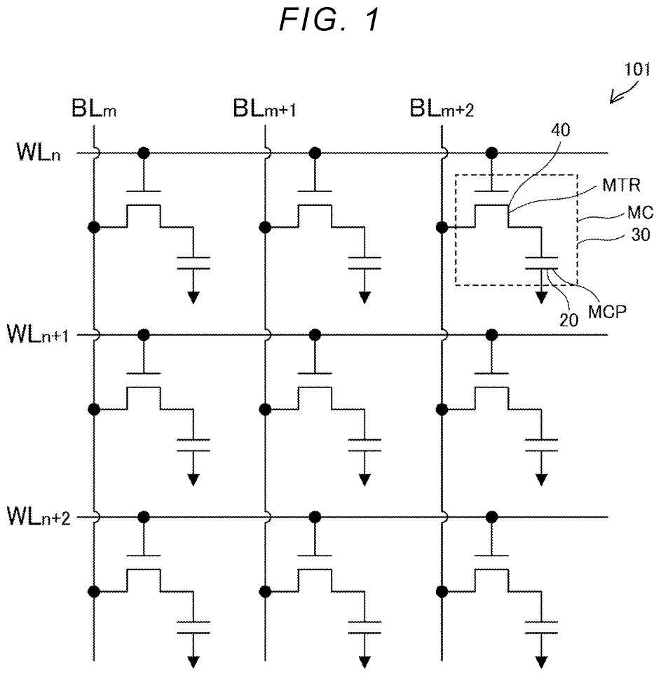

As shown in FIG. 1, the memory cell array is provided with a plurality of memory cells MC, a plurality of word lines WL, and a plurality of bit lines BL.

In FIG. 1, as an example of the plurality of word lines WL, a word line WLₙ, a word line WLₙ₊₁, and a word line WLₙ₊₂ are shown (here, n is a positive integer). In addition, in FIG. 1, as an example of the bit line BL, a bit line BLₘ, a bit line BLₘ₊₁, and a bit line BLₘ₊₂ are shown (here, m is a positive integer). The number of the plurality of memory cells MC is not limited to the number shown in FIG. 1.

The plurality of memory cells MC are arranged in a matrix shape, for example, to form a memory cell array. The memory cell MC is provided with a memory transistor MTR which is a field effect transistor (FET) and a memory capacitor MCP.

A series of memory cells MC provided along the row direction are connected to a word line WL (for example, a word line WLₙ) corresponding to a row (for example, an n-th row) to which the memory cells MC belong. A series of memory cells MC provided along the column direction are connected to the bit line BL (for example, the bit line BLₘ₊₂) corresponding to the column (for example, the m+2-th column) to which the memory cells MC belong.

Specifically, the gate of the memory transistor MTR provided in the memory cell MC is connected to the word line WL corresponding to the row to which the memory cell MC belongs. One of the source and the drain of the memory transistor MTR is connected to the bit line BL corresponding to the column to which the memory cell MC belongs.

One electrode of the memory capacitor MCP provided in the memory cell MC is connected to the other of the source and the drain of the memory transistor MTR provided in the memory cell MC. The other electrode of the memory cell MC is connected to a power supply line (not shown) that supplies a specific potential.

The memory cell MC is capable of storing data by accumulating charges in the memory capacitor MCP with a current flowing through the corresponding bit line BL by switching of the memory transistor MTR based on the potential of the corresponding word line WL.

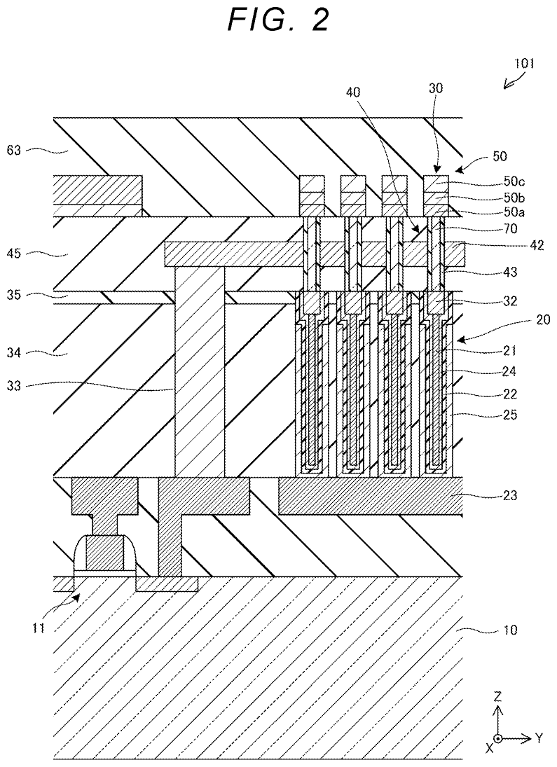

As shown in FIG. 2, the semiconductor storage device 101 is provided with a semiconductor substrate 10, a circuit 11, a capacitor 20, a semiconductor device 30, a conductor 33, and insulating layers 34, 35, 45, and 63.

The capacitor 20 is provided with a conductor 21, an insulating film 22 (an example of a “dielectric film”), a conductor 23, a capacitor electrode 24 (an example of a “first capacitor electrode”), and a capacitor electrode 25 (an example of a “second capacitor electrode”).

The semiconductor device 30 is provided with a field effect transistor 40 (an example of a “semiconductor element”), an upper electrode 50 (an example of a “first electrode”) provided on the upper side of the field effect transistor 40, and a lower electrode 32 (an example of a “second electrode”) provided on the lower side of the field effect transistor 40.

The field effect transistor 40 is provided with an oxide semiconductor layer 70 (an example of an “oxide semiconductor”) corresponding to a channel, a gate insulating film 43, and a conductive layer 42 (an example of a “gate electrode”).

The oxide semiconductor layer 70 is formed in the insulating layer 45 (an example of the “first insulating layer”) and has an upper end 70a (an example of the “first end”) and a lower end 70b (an example of the “second end”). The oxide semiconductor layer 70 is a columnar body extending from a lower end 70b to an upper end 70a in a Z-axis+direction (an example of a “first direction”). The oxide semiconductor layer 70 forms a channel of the field effect transistor 40, and the oxide semiconductor layer 70 has an amorphous structure.

The conductive layers 42 function as gate electrodes of the field effect transistor 40, and face each other via the gate insulating film 43 between the upper end 70a and the lower end 70b of the oxide semiconductor layer 70.

The gate insulating film 43 is, for example, a silicon nitride film (Si₃N₄) containing silicon and nitrogen, for example.

The upper electrode 50 is formed in the Z-axis+direction with respect to the oxide semiconductor layer 70. The upper electrode 50 is provided with a metal oxide layer 50a (an example of the “first conductive film” and an example of the “first metal oxide electrode portion”), a barrier metal layer 50b (an example of the “first barrier metal portion”), and a metal film 50c (an example of the “first metal film” and an example of the “pad”).

The metal film 50c contains tungsten (W) (an example of a “first metal atom”). The metal oxide layer 50a is formed between the metal film 50c and the upper end 70a (an example of a “first end”) of the oxide semiconductor layer 70 and contains a metal oxide. The metal oxide contains, for example, indium and tin as metal elements. In the present embodiment, the metal oxide layer 50a is formed of indium-tin-oxide (ITO).

The barrier metal layer 50b contains titanium and nitrogen and is formed between the metal oxide layer 50a and the metal film 50c. In the present embodiment, the barrier metal layer 50b is formed of, for example, titanium nitride (TiN).

The lower electrode 32 is in contact with the lower end 70b (an example of a “second end”) of the oxide semiconductor layer 70. The lower electrode 32 is formed of, for example, an ITO layer containing a metal oxide such as indium-tin-oxide (ITO).

The circuit 11 configures a peripheral circuit such as a decoder for selecting a predetermined memory cell MC, a sense amplifier connected to the bit line BL, and a register configured with an SRAM, among the plurality of memory cells MC of the semiconductor storage device 101, that is, the capacitor 20 and the field effect transistor 40. The circuit 11 may include a CMOS circuit having a field effect transistor of a P-channel type field effect transistor (Pch-FET) and an N-channel type field effect transistor (Nch-FET), which are formed by a CMOS process.

The field effect transistor of the circuit 11 can be formed using, for example, a semiconductor substrate 10 such as a single crystal silicon substrate. The Pch-FET and the Nch-FET are so-called horizontal field effect t transistors having a channel region, a source region, and a drain region in the semiconductor substrate 10, and having a channel for causing a carrier to flow in the X-axis direction or the Y-axis direction substantially parallel to the surface of the semiconductor substrate 10 in a region close to the surface of the semiconductor substrate 10. The semiconductor substrate 10 may have a conductive type of P-type or N-type. For convenience, FIG. 2 shows an example of the field effect transistor of the circuit 11.

The capacitor 20 is a memory capacitor MCP provided in the memory cell MC (refer to FIG. 1). Although four capacitors 20 are shown in FIG. 2, the number of capacitors 20 is not limited to four.

In the present embodiment, the capacitor 20 is provided on the upper side of the semiconductor substrate 10. The capacitor electrode 24 in the capacitor 20 is connected to the conductor 21 and the lower electrode 32. The capacitor electrode 25 faces the capacitor electrode 24. The insulating film 22 is provided between the capacitor electrode 24 and the capacitor electrode 25.

The capacitor 20 is a three-dimensional capacitor such as a pillar-type capacitor. As the capacitor of the present embodiment, another capacitor having a configuration capable of accumulating charges may be adopted.

The conductor 21 has a shape that is in contact with the end surface of the lower electrode 32 on the lower side and extends from the end portion toward the lower side. The capacitor electrode 24 covers the lower electrode 32 and the conductor 21. The insulating film 22 covers the capacitor electrode 24. The capacitor electrode 25 has a lower end that surrounds a part of the insulating film 22 on the lower side and is in contact with an end surface of the conductor 23 on the upper side.

The conductor 21 may contain a material such as amorphous silicon. The insulating film 22 may contain a material such as hafnium oxide. The conductor 23 and the capacitor electrodes 24 and 25 may contain materials such as tungsten (W) and titanium nitride (TiN).

The conductor 33 is provided with a wiring that electrically connects the circuit 11 and the semiconductor device 30. The conductor 33 may be provided with a via wiring, and for example, as shown in FIG. 2, has a via wiring that extends in the Z-axis direction and connects the word line WL and the circuit 11 provided on the semiconductor substrate 10. The conductor 33 contains, for example, copper.

The insulating layer 34 is provided between the plurality of capacitors 20. The insulating layer 34 is, for example, a silicon oxide film containing silicon and oxygen.

The insulating layer 35 is provided on the upper side of the insulating layer 34. The insulating layer 35 is, for example, a silicon nitride film containing silicon and nitrogen.

The semiconductor device 30 is provided on the upper side of the capacitor 20. The field effect transistor 40 in the semiconductor device 30 corresponds to the memory transistor MTR of the memory cell MC (refer to FIG. 1).

In the semiconductor device 30, the field effect transistor 40 is provided on the upper side of the lower electrode 32. Specifically, the oxide semiconductor layer 70 of the field effect transistor 40 is located on the lower electrode 32 in a direction away from the semiconductor substrate 10, that is, on the upper side.

The upper electrode 50 is located on the oxide semiconductor layer 70 in a direction away from the semiconductor substrate 10, that is, on the upper side. With such a configuration, the field effect transistor 40 is a so-called vertical transistor having a channel extending in the Z-axis direction (up-down direction) substantially perpendicular to the surface of the semiconductor substrate 10.

In addition, the oxide semiconductor layer 70 is a semiconductor in which oxygen deficiency acts as a donor, and contains indium (In), zinc (Zn), and gallium (Ga) as metal elements. Specifically, the oxide semiconductor layer 70 is an oxide of indium, gallium, and zinc, that is, IGZO (InGaZnO). The oxide semiconductor layer 70 may be another type of oxide semiconductor.

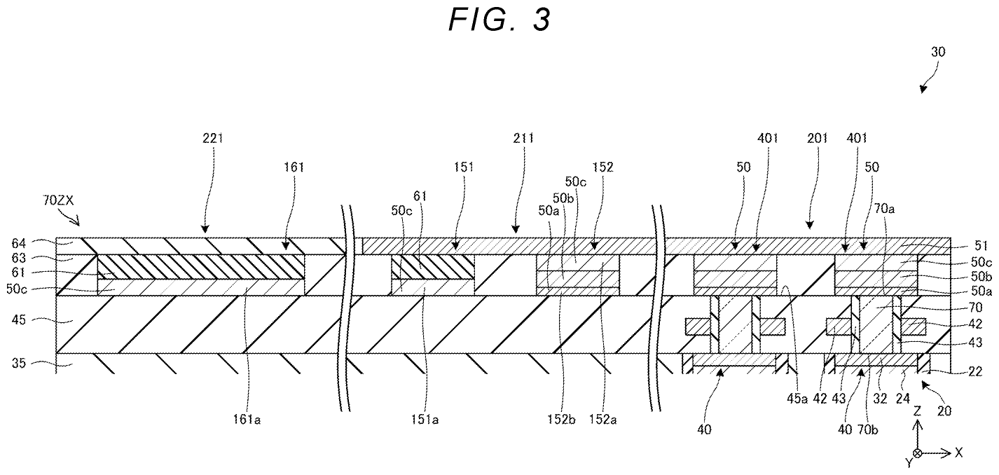

FIG. 3 shows a cross-sectional view of the semiconductor device 30 viewed in a cross section 70ZX parallel to the ZX plane and included in the oxide semiconductor layer 70.

As shown in FIG. 3, in the present embodiment, the semiconductor device 30 is further provided with the dummy electrodes 151 and 152 (an example of the “first structure”) and the mark electrode 161 (an example of the “first structure”).

The group 401 is provided with the capacitor 20, the lower electrode 32, the oxide semiconductor layer 70, and the upper electrode 50. The group 401 is provided with the landing pad (LP) array unit 201. The dummy electrode 151 and the dummy electrode 152 are provided in the dummy LP array unit 211. The mark electrode 161 is provided in the projection portion Peri portion mark 221.

The insulating layer 45 has a main surface 45a (an example of a “first surface”) continuous with the contact surface between the upper end 70a of the oxide semiconductor layer 70 and the metal oxide layer 50a on the upper side. The main surface 45a is substantially parallel to the XY plane.

The conductive layer 51 corresponds to the bit line BL (refer to FIG. 1) and extends along an extension axis parallel to the X-axis. The conductive layer 42 corresponds to the word line WL (refer to FIG. 1) and extends along an extension axis parallel to the Y-axis.

In the semiconductor device 30, two or more conductive layers 42 are repeatedly provided in the X-axis direction. Two or more conductive layers 51 are repeatedly provided in the Y-axis direction.

The dummy electrode 151 (an example of the “first structure”) and the mark electrode 161 (an example of the “first structure”) are separated from the upper electrode 50 in a second direction intersecting the Z-axis+direction, for example, in an X-axis−direction.

The dummy electrode 151 and the mark electrode 161 contain at least tungsten and do not contain a metal oxide.

Specifically, the dummy electrode 151 is provided with a metal film 50c (hereinafter, may be referred to as a second metal film 151a) and a hard mask layer 61. The mark electrode 161 is provided with a metal film 50c (hereinafter, may be referred to as a second metal film 161a) and a hard mask layer 61.

That is, unlike the upper electrode 50, the dummy electrode 151 and the mark electrode 161 are not provided with the metal oxide layer 50a.

The dummy electrode 152 is provided with a metal oxide layer 50a (hereinafter, may be referred to as a second conductive film 152b) containing a metal oxide and in contact with the main surface 45a, a metal film 50c (hereinafter, may be referred to as a third metal film 152a) formed on the upper side of the metal oxide layer 50a and containing tungsten, and a barrier metal layer 50b provided between the metal oxide layer 50a and the metal film 50c.

The second metal films 151a and 161a and the third metal film 152a have the same composition as the metal film 50c provided in the upper electrode 50. Specifically, the second metal films 151a and 161a, the third metal film 152a, and the metal film 50c in the upper electrode 50 are formed as film at the same time during the manufacturing. Therefore, the second metal films 151a and 161a, the third metal film 152a, and the metal film 50c in the upper electrode 50 have the same composition.

In addition, the second metal films 151a and 161a and the third metal film 152a have the same thickness as the thickness of the metal film 50c in the upper electrode 50 (an example of the “first thickness”).

In addition, the second metal films 151a and 161a are provided in contact with the main surface 45a. On the other hand, the metal film 50c and the third metal film 152a in the upper electrode 50 are provided away from the main surface 45a. Specifically, the metal film 50c and the third metal film 152a in the upper electrode 50 are connected to the main surface 45a via the barrier metal layer 50b and the metal oxide layer 50a.

The conductive layer 51 (an example of a “signal line”) is formed such that the metal film 50c, the barrier metal layer 50b, and the second metal film 151a are provided between the conductive layer 51 and the insulating layer 45, and is in contact with the metal film 50c in the upper electrode 50.

In the present embodiment, the conductive layer 51 is formed on the upper side of the dummy electrodes 151 and 152 and the upper electrode 50. The third metal film 152a in the dummy electrode 152 and the metal film 50c in the upper electrode 50 are in contact with the conductive layer 51. The second metal film 151a in the dummy electrode 151 is connected to the conductive layer 51 through the hard mask layer 61.

The insulating layer 63 (an example of a “second insulating layer”) is formed on the upper side of the insulating layer 45. The insulating layer 63 and the insulating layer 64 provided on the upper side of the insulating layer 63 surround the mark electrode 161. The insulating layers 63 and 64 are formed of, for example, an oxide insulator such as silicon dioxide. The mark electrode 161 is used, for example, in a manufacturing process to align a relative position with a mask or the like with respect to the wafer of the semiconductor device 30.

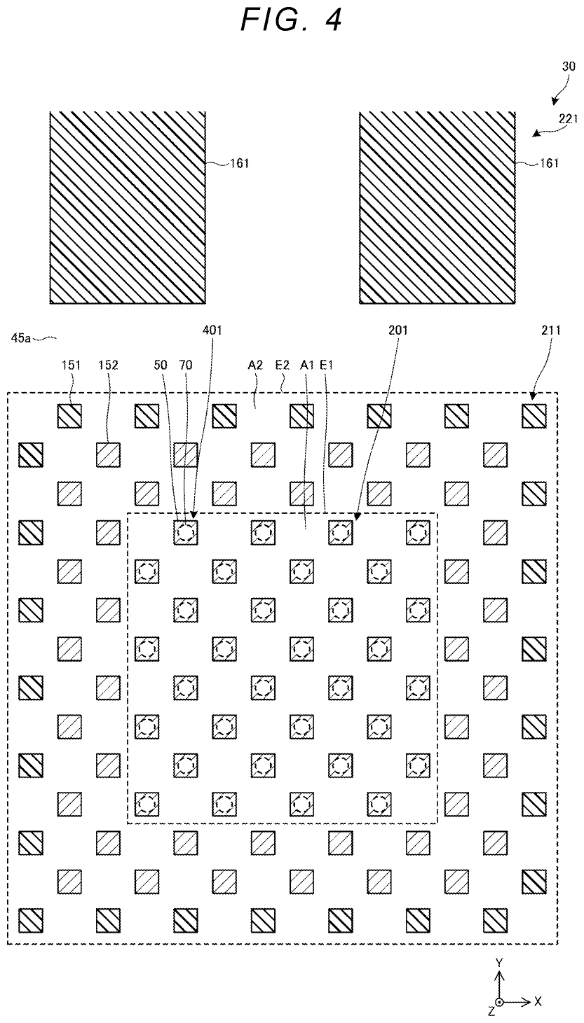

FIG. 4 is a diagram showing an example of a plan view of the semiconductor device 30 when the main surface 45a of the insulating layer 45 is viewed in a plan view along the up-down direction.

As shown in FIGS. 3 and 4, when the main surface 45a is viewed in a plan view along the up-down direction, the plurality of groups 401 are two-dimensionally arranged in an area A1 (an example of a “first area”). The area A1 is, for example, a range surrounded by the outer edge E1.

The area A2 (an example of a “second area”) is located along the outer edge E1 of the area A1. The area A2 is a range surrounded by the outer edge E2 of the area A2, and is a range outside the outer edge E1 of the area A1.

A plurality of the dummy electrodes 151 and a plurality of the dummy electrodes 152 are two-dimensionally arranged in the area A2.

When the main surface 45a is viewed in a plan view along the up-down direction, the plurality of dummy electrodes 151 are provided along the outer edge E2 of the area A2. Specifically, the plurality of dummy electrodes 151 are provided in one layer at an immediately inner side of the outer edge E2 of the area A2. The plurality of dummy electrodes 151 may be provided in two or more layers immediately at an immediately inner side of the outer edge E2 of the area A2.

A plurality of dummy electrodes 152 are provided in two layers between the plurality of dummy electrodes 151 and the plurality of groups 401. The plurality of dummy electrodes 152 may be provided in one layer or may be provided in three or more layers.

When the main surface 45a is viewed in a plan view along the up-down direction, the area of the mark electrode 161 is larger than the area of each of the upper electrode 50, the dummy electrode 151, and the dummy electrode 152.

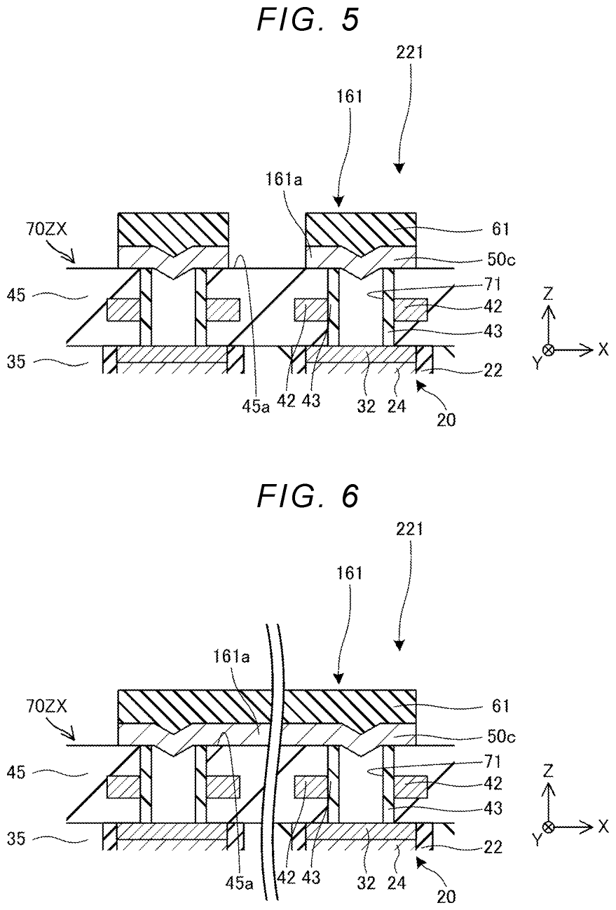

FIG. 5 shows a cross-sectional view of the first modification example of the projection portion Peri portion mark 221 parallel to the ZX plane. As shown in FIG. 5, the first modification example of the projection portion Peri portion mark 221 is provided with the hole portion 71 that overlaps the second metal film 161a and penetrates the insulating layer 45 when the insulating layer 45 is viewed in the up-down direction.

Specifically, the hole portion 71, the lower electrode 32, the conductive layer 42, the gate insulating film 43, and the capacitor 20 are formed on the lower side of the second metal film 161a.

The hole portion 71 has, for example, the same shape as a through-hole in which the oxide semiconductor layer 70 is formed in the field effect transistor 40.

The hard mask layer 61 and the second metal film 161a have a shape that protrudes toward the lower side as the hard mask layer 61 and the second metal film 161a are closer to the central axis of the hole portion 71.

FIG. 6 shows a cross-sectional view parallel to the ZX plane of the second modification example of the projection portion Peri portion mark 221. As shown in FIG. 6, the second modification example of the projection portion Peri portion mark 221 is different from the first modification example of the projection portion Peri portion mark 221 shown in FIG. 5 in that the hard mask layer 61 and the second metal film 161a are provided over the plurality of hole portions 71.

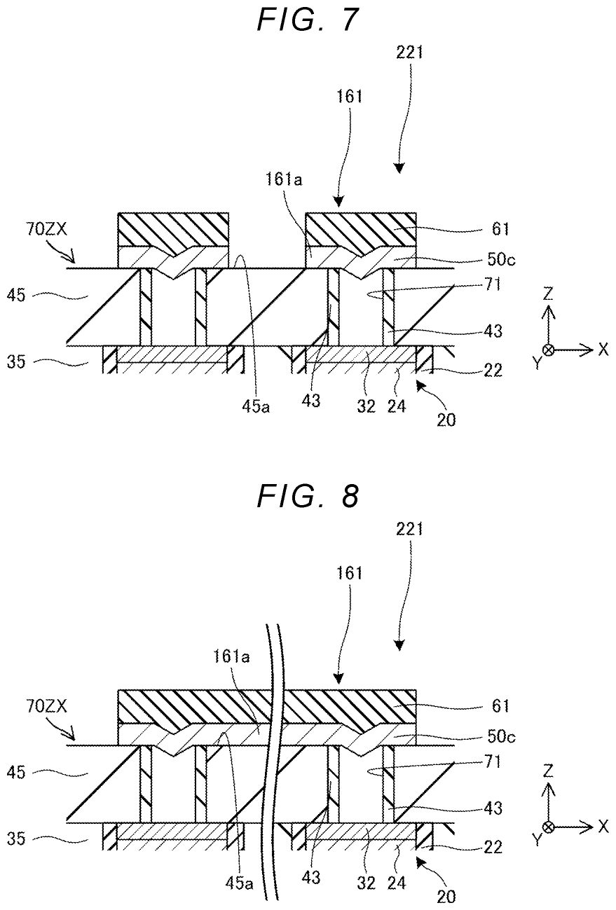

FIG. 7 shows a cross-sectional view parallel to the ZX plane of the third modification example of the projection portion Peri portion mark 221. As shown in FIG. 7, the third modification example of the projection portion Peri portion mark 221 is different from the first modification example of the projection portion Peri portion mark 221 shown in FIG. 5 in that the conductive layer 42 is not formed on the lower side of the second metal film 161a.

FIG. 8 shows a cross-sectional view of the projection portion Peri portion mark 221 according to the fourth modification example parallel to the ZX plane. As shown in FIG. 8, the fourth modification example of the projection portion Peri portion mark 221 is different from the second modification example of the projection portion Peri portion mark 221 shown in FIG. 6 in that the conductive layer 42 is not formed on the lower side of the second metal film 161a.

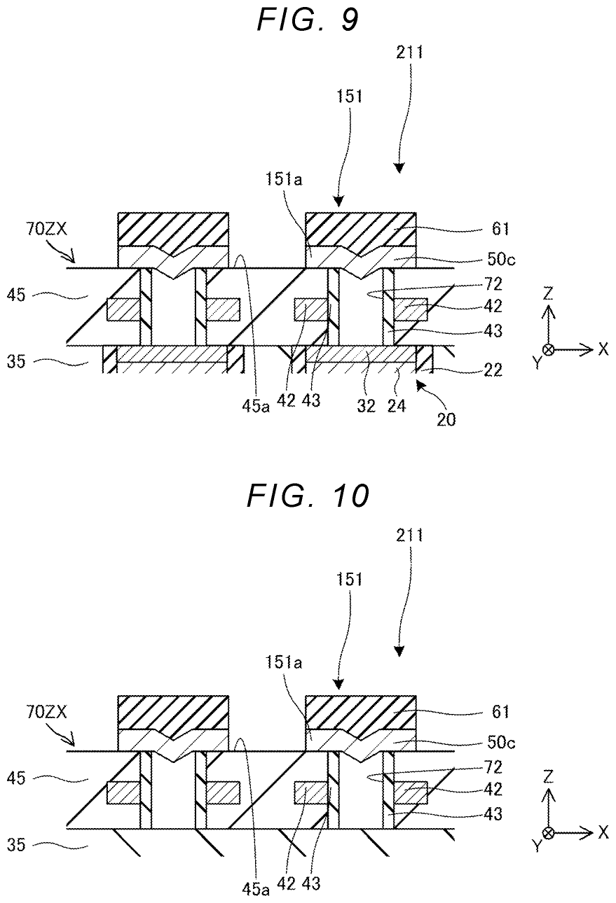

FIG. 9 shows a cross-sectional view of the first modification example of the dummy LP array unit 211 parallel to the ZX plane. As shown in FIG. 9, the first modification example of the dummy LP array unit 211 is provided with the hole portion 72 that overlaps the second metal film 151a and penetrates the insulating layer 45 when the insulating layer 45 is viewed in the up-down direction.

Specifically, the hole portion 72, the lower electrode 32, the conductive layer 42, the gate insulating film 43, and the capacitor 20 are formed on the lower side of the second metal film 151a.

The hole portion 72 has, for example, the same shape as a through-hole in which the oxide semiconductor layer 70 is formed in the field effect transistor 40.

The hard mask layer 61 and the second metal film 151a have a shape that protrudes toward the lower side as the hard mask layer 61 and the second metal film 151a are closer to the central axis of the hole portion 72.

FIG. 10 shows a cross-sectional view of the dummy LP array unit 211 of the second modification example parallel to the ZX plane. As shown in FIG. 10, the second modification example of the dummy LP array unit 211 is different from the first modification example of the dummy LP array unit 211 shown in FIG. 9 in that the lower electrode 32 and the capacitor 20 are not formed on the lower side of the second metal film 151a.

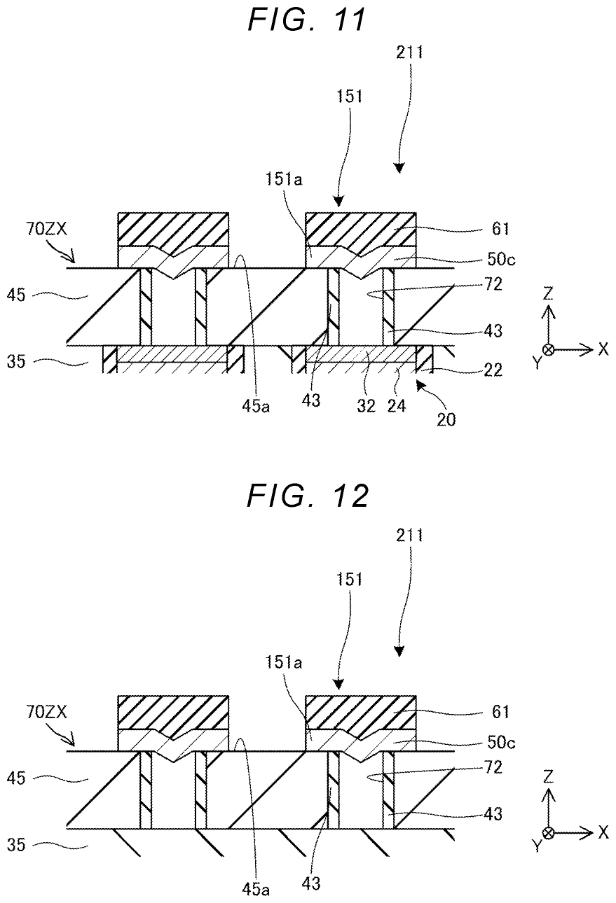

FIG. 11 shows a cross-sectional view of the third modification example of the dummy LP array unit 211 parallel to the ZX plane. As shown in FIG. 11, the third modification example of the dummy LP array unit 211 is different from the first modification example of the dummy LP array unit 211 shown in FIG. 9 in that the conductive layer 42 is not formed on the lower side of the second metal film 151a.

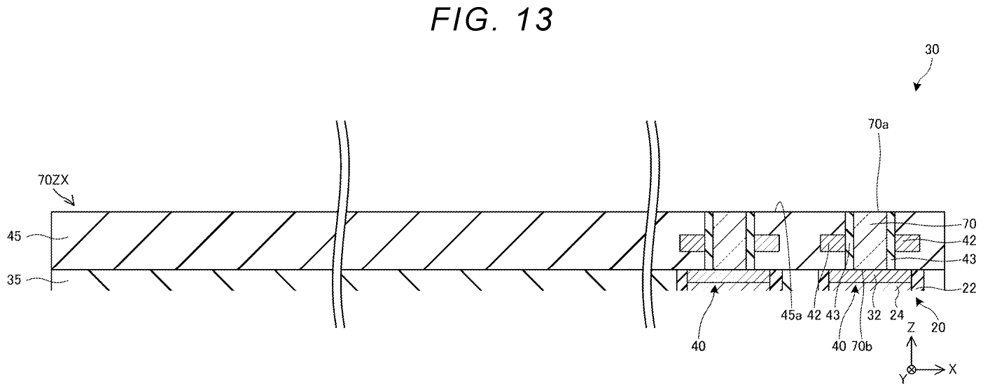

FIG. 12 shows a cross-sectional view of the fourth modification example of the dummy LP array unit 211 parallel to the ZX plane. As shown in FIG. 12, the fourth modification example of the dummy LP array unit 211 is different from the third modification example of the dummy LP array unit 211 shown in FIG. 11 in that the lower electrode 32 and the capacitor 20 are not formed on the lower side of the second metal film 151a.

### Manufacturing Method for Semiconductor Device

Hereinafter, a manufacturing method for the semiconductor device 30 will be described as an example of a manufacturing method for a semiconductor device according to the first embodiment.

First, as shown in FIG. 13, the oxide semiconductor layer 70 is formed in the through-hole formed in the insulating layer 45.

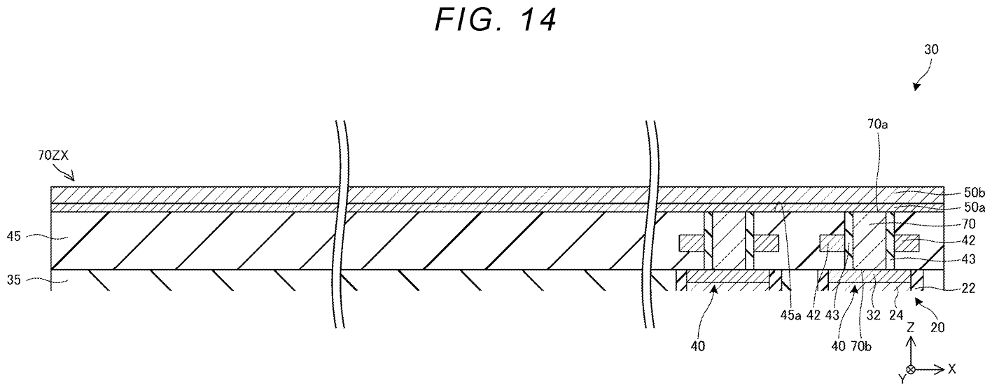

Next, as shown in FIG. 14, the metal oxide layer 50a is formed on the main surface 45a of the insulating layer 45. Then, the barrier metal layer 50b is formed on the surface of the metal oxide layer 50a on the upper side.

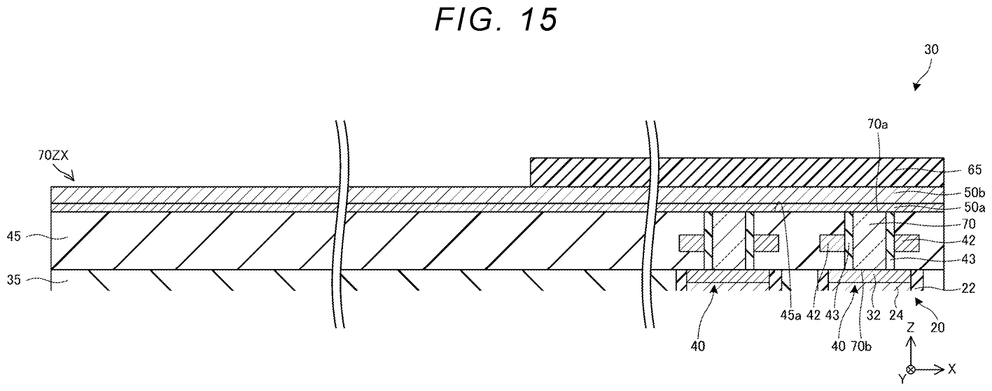

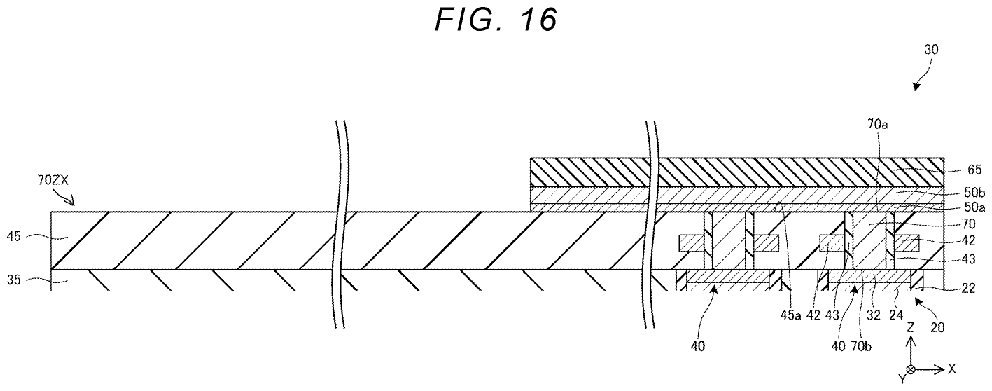

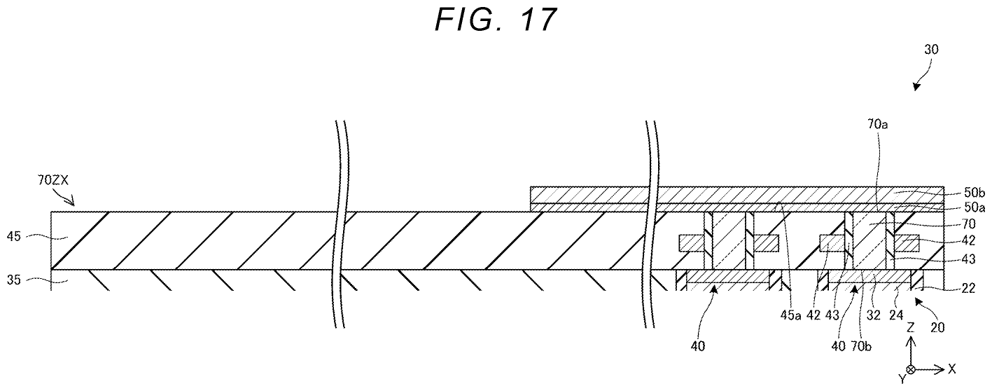

Next, as shown in FIG. 15, the hard mask layer 65 is formed in a region where the upper electrode 50 and the dummy electrode 152 are to be formed on the surface of the barrier metal layer 50b on the upper side.

Next, as shown in FIG. 16, in a region where the hard mask layer 65 is not formed, the metal oxide layer 50a and the barrier metal layer 50b are removed by etching.

Next, as shown in FIG. 17, the hard mask layer 65 is removed.

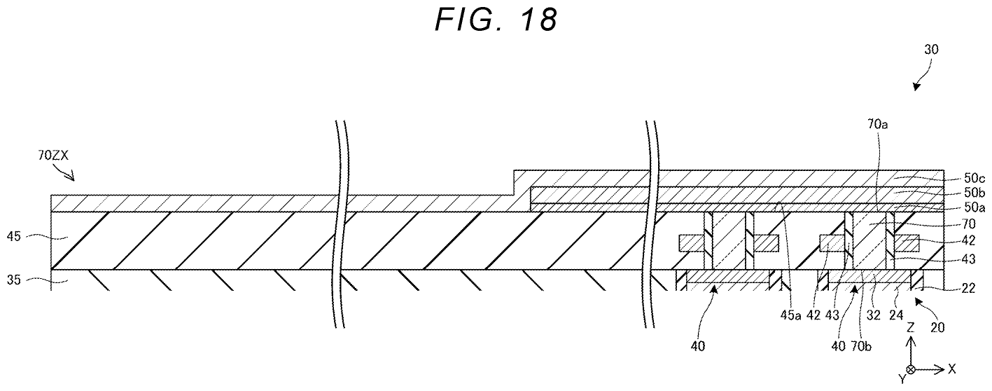

Next, as shown in FIG. 18, the metal film 50c is formed on the surface of the exposed main surface 45a and barrier metal layer 50b on the upper side.

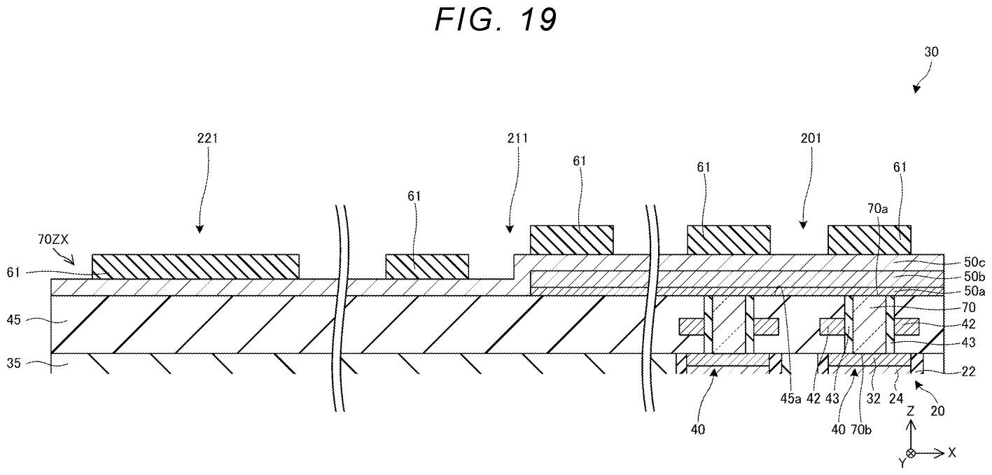

Next, as shown in FIG. 19, the hard mask layer 61 is formed in a region where the upper electrode 50, the dummy electrode 151, the dummy electrode 152, and the mark electrode 161 are to be formed on the surface of the metal film 50c on the upper side.

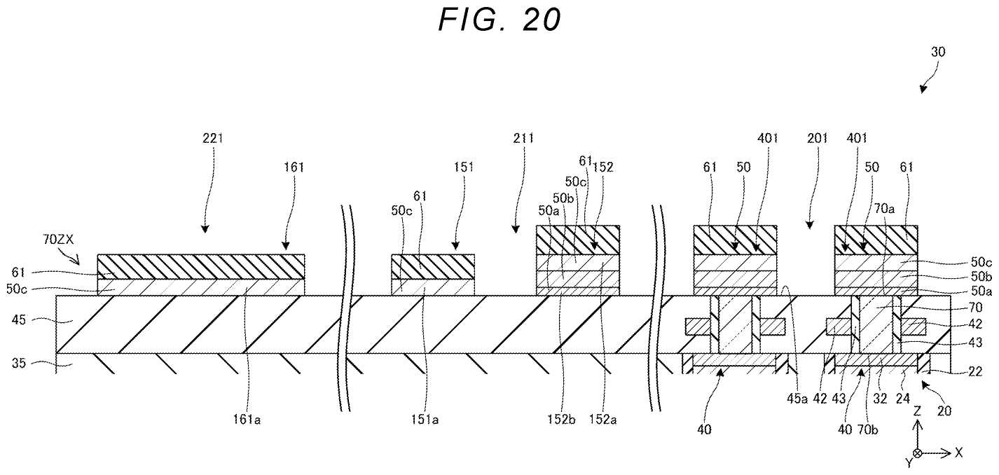

Next, as shown in FIG. 20, in a region where the hard mask layer 61 is not formed, the metal oxide layer 50a, the barrier metal layer 50b, and the metal film 50c are removed by reactive ion etching.

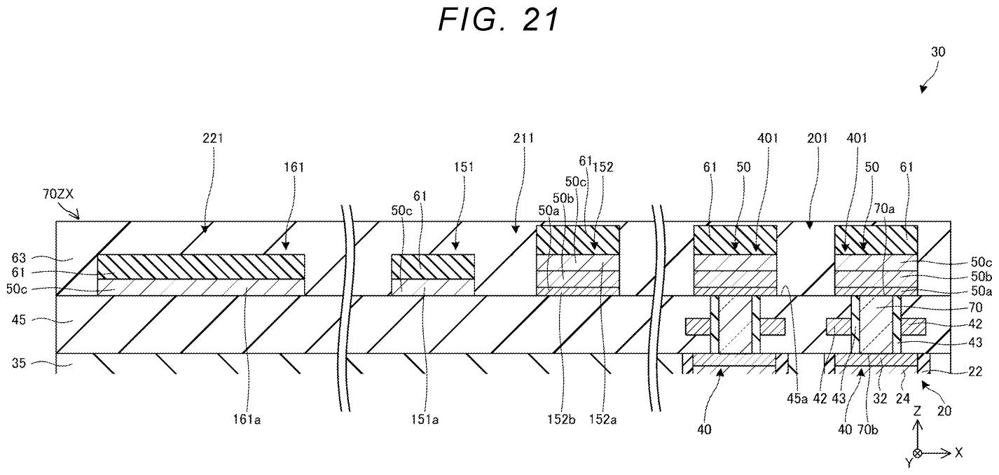

Next, as shown in FIG. 21, an insulating layer 63 is formed on the upper side of the semiconductor device 30 to cover the hard mask layer 61.

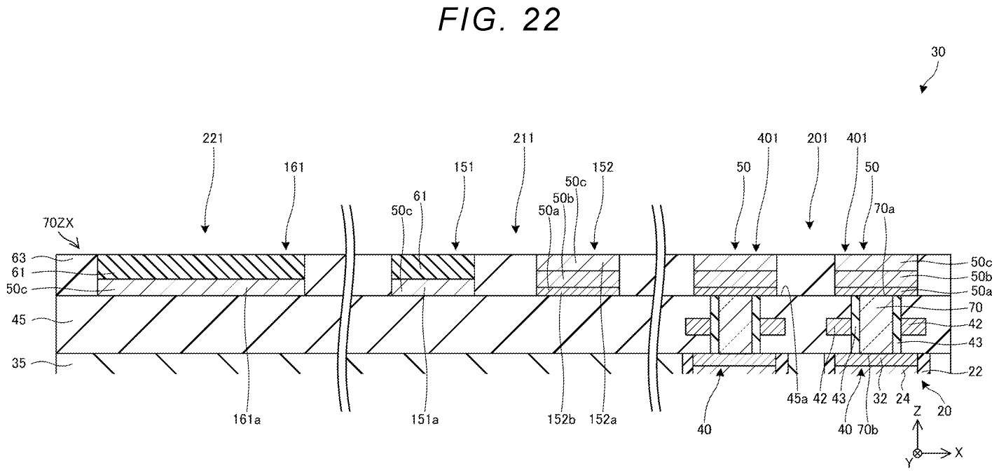

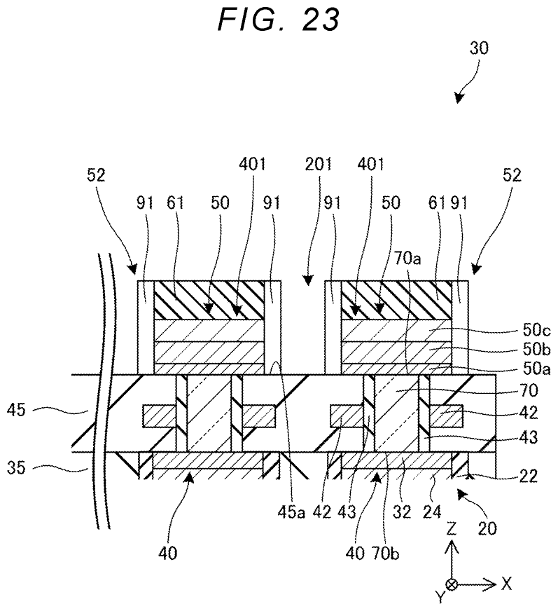

Next, as shown in FIG. 22, the surface of the insulating layer 63 on the upper side is subjected to chemical mechanical polishing, so that the metal film 50c in the dummy electrode 152, that is, the third metal film 152a and the metal film 50c in the upper electrode 50 are exposed.

Next, as shown in FIG. 3, the conductive layer 51 is formed over the LP array unit 201 and the dummy LP array unit 211. In addition, the insulating layer 64 is formed in the projection portion Peri portion mark 221.

### Effect

As shown in FIG. 23, when the metal oxide layer 50a is removed (refer to FIG. 20), the residue 91 generated during the ITO process may adhere to the periphery of the pillar 52 formed of the metal oxide layer 50a, the barrier metal layer 50b, the metal film 50c, and the hard mask layer 61.

Since the residues 91 may block the gap between the pillars 52, the residues 91 are not preferable. Such blocking between the pillars 52 occurs significantly in the pillars 52 close to the outer edge of the region in which a plurality of the pillars 52 are provided in a two-dimensional array.

On the other hand, in the present embodiment, as shown in FIGS. 3 and 4, the dummy electrode 151 that is not provided with the metal oxide layer 50a is provided in the vicinity of the outer edge E2 of the area A2 instead of the dummy electrode 152 that is provided with the metal oxide layer 50a.

With such a configuration, when the metal oxide layer 50a is removed (refer to FIG. 20), the amount of the residue 91 adhering to the periphery of the dummy electrode 151 can be reduced. Accordingly, the blocking between the dummy electrode 151 and the dummy electrode 151 and between the dummy electrode 151 and the dummy electrode 152 due to the residue 91 can be reduced.

In addition, the metal oxide layer 50a is removed under dry conditions (refer to FIG. 20), but when the metal oxide layer 50a is provided in the projection portion Peri portion mark 221 having a large area for example, contamination in the chamber due to the residue 91 is a problem.

On the other hand, in the present embodiment, as shown in FIGS. 3 and 4, the metal oxide layer 50a is not provided in the mark electrode 161 in the projection portion Peri portion mark 221.

With such a configuration, when the metal oxide layer 50a, the barrier metal layer 50b, and the metal film 50c are removed by reactive ion etching as shown in FIG. 20, the amount of the residue 91 generated from the projection portion Peri portion mark 221 can be reduced. Accordingly, contamination in the chamber due to the residue 91 can be reduced. Therefore, a high-quality semiconductor device 30 can be manufactured.

### Second Embodiment

The semiconductor device 30 according to the second embodiment will be described. In the following second embodiment and later, the description of matters common to the first embodiment will be omitted, and only different points will be described. In particular, the same effects of the same configurations will not be successively described for each embodiment.

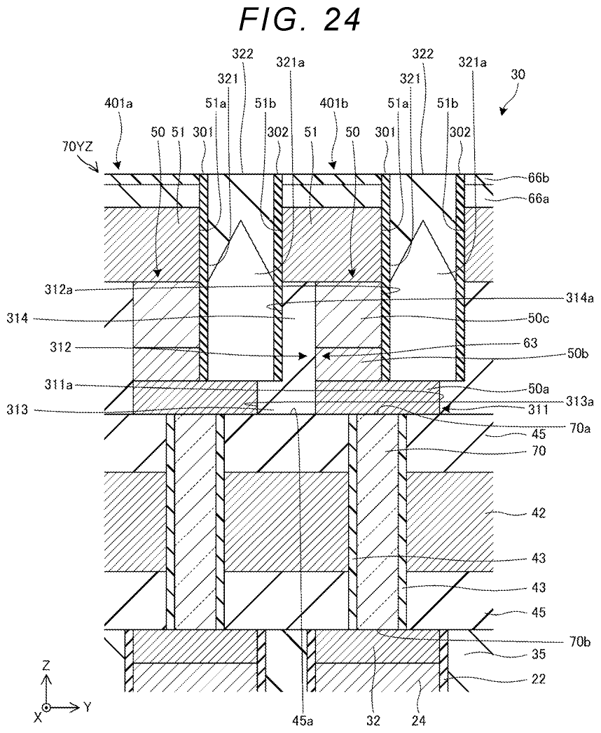

As shown in FIG. 24, in the first embodiment, the semiconductor device 30 when viewed in the cross section 70ZX parallel to the ZX plane was described, but in the second embodiment, the semiconductor device 30 when viewed in the cross section 70YZ parallel to the YZ plane and included in the oxide semiconductor layer 70 will be described.

Hereinafter, a first example of the semiconductor device 30 according to the second embodiment (hereinafter, may be referred to as the first example of the second embodiment) will be described.

### First Example of Second Embodiment

The upper electrode 50 is provided with a portion 311 (an example of the “first portion”) in the Z-axis−direction, that is, on the lower side, and a portion 312 (an example of the “second portion”) in the Z-axis+direction, that is, on the upper side.

The portion 311 is in contact with the upper end 70a of the oxide semiconductor layer 70 and has a side surface 311a (an example of a “first side surface”) in the Y-axis+direction (an example of a “second direction”).

The portion 311 contains indium and tin as metal elements and is provided with at least a metal oxide layer 50a (an example of a “first metal oxide electrode portion”) provided on the lower side of the portion 311. In the first example of the second embodiment, the metal oxide layer 50a formed of indium-tin-oxide (ITO) is provided in the entirety of the portion 311.

The portion 312 is provided on the upper side of the portion 311 and has a side surface 312a (an example of a “second side surface”) in the Y-axis+direction. The portion 312 contains tungsten and is provided with at least a metal film 50c (an example of a “pad”) provided on the upper side of the portion 312.

In the first example of the second embodiment, the portion 312 is provided with the metal film 50c and the barrier metal layer 50b (an example of the “first barrier metal portion”) provided on the lower side of the metal film 50c and containing titanium and nitrogen.

In the first example of the second embodiment, the surface of the metal oxide layer 50a on the upper side in the portion 311 and the surface of the barrier metal layer 50b on the lower side in the portion 312 are in contact with each other.

In the present embodiment, in the cross section 70YZ, the side surface of the portion 311 in the Y-axis−direction and the side surface of the portion 312 in the Y-axis−direction are smoothly continuous. In the cross section 70YZ, the side surface 311a of the portion 311 in the Y-axis+direction is located in the Y-axis+direction with respect to the side surface 312a of the portion 312 in the Y-axis+direction. That is, the width of the portion 311 in the Y−axis direction is larger than the width of the portion 312 in the Y-axis direction.

The insulating layer 63 (an example of a “second insulating layer”) is provided in the Y-axis−direction with respect to the upper electrode 50 and is provided on the upper side of the insulating layer 45. The insulating layer 63 is provided with a portion 313 (an example of a “third portion”) on the lower side and a portion 314 (an example of a “fourth portion”) on the upper side.

The portion 313 is in contact with the main surface 45a of the insulating layer 45 and has a side surface 313a (an example of a “third side surface”) in the Y-axis−direction.

The portion 314 is provided on the upper side of the portion 313 and has a side surface 314a (an example of a “fourth side surface”) in the Y-axis−direction. As will be described later, since the insulating layer 63 having a layered shape is etched to form the portions 313 and 314, the portions 313 and 314 are integrated with each other.

In the present embodiment, in the cross section 70YZ, the side surface of the portion 313 in the Y-axis+direction and the side surface of the portion 314 in the Y-axis+direction are in contact with the side surface of the upper electrode 50 in the Y-axis−direction and are smoothly continuous. In the cross section 70YZ, the side surface 313a of the portion 313 in the Y-axis−direction is located in the Y-axis−direction with respect to the side surface 314a of the portion 314 in the Y-axis−direction. That is, the width of the portion 313 in the Y-axis direction is larger than the width of the portion 314 in the Y-axis direction.

The conductive layer 51 is provided on the upper side of the upper electrode 50 and the insulating layer 63. The conductive layer 51 extends along the X-axis+direction (an example of the “third direction”). In the semiconductor device 30, two or more conductive layers 51 are provided. The two or more conductive layers 51 are repeatedly provided at a constant interval in the Y-axis direction. Insulating layers 66a and 66b are provided on the upper side of the conductive layer 51.

The conductive layer 42 extends in the Y-axis+direction. In the semiconductor device 30, two or more conductive layers 42 are provided. The two or more conductive layers 42 are repeatedly provided at a constant interval in the X-axis+direction.

The liner film 301 (an example of a “first film”) covers the side surface 312a, the side surface 51a of the conductive layer 51 in the Y-axis+direction, and the side surfaces of the insulating layers 66a and 66b in the Y-axis+direction.

The liner film 302 (an example of a “second film”) covers the side surface 314a, the side surface 51b of the conductive layer 51 in the Y-axis−direction, and the side surfaces of the insulating layers 66a and 66b in the Y-axis−direction.

The liner films 301 and 302 are formed of silicon nitride or aluminum oxide and have a function of reducing the permeation of oxygen.

The group 401 is provided with the upper electrode 50, the oxide semiconductor layer 70, the lower electrode 32, the insulating layers 63, 66a, and 66b, and the liner films 301 and 302. The semiconductor device 30 is provided with two or more groups 401. Two or more groups 401 are provided for each conductive layer 51 and each conductive layer 42.

Hereinafter, of the two continuous groups 401, the group 401 in the Y-axis−direction may be referred to as a group 401a (an example of a “first group”). In addition, of the two continuous groups 401, the group 401 in the Y-axis+direction may be referred to as a group 401b (an example of a “second group”).

In the first example of the second embodiment, the entire side surface 311a of the portion 311 in the group 401a and the entire side surface 313a of the portion 313 in the group 401b are in contact with each other.

The BL-LP groove portion 321 in which the upper side is open and the lower side is a lower surface is formed between the group 401a and the group 401b.

The liner film 301 provided in the group 401a and the liner film 302 provided in the group 401b face each other.

The liner films 301 and 302 respectively provided in the groups 401a and 401b are the side surfaces of the BL-LP groove portion 321.

An air gap 321a is provided between the group 401a and the group 401b. An insulating layer 322 (an example of a “third insulating layer”) is provided on the upper side with respect to the air gap 321a. The insulating layer 322 is formed of, for example, an insulator such as silicon oxide.

The upper side of the air gap 321a is blocked by the insulating layer 322. As a result, the mechanical strength against chemical mechanical polishing can be improved, and the material of the film can be prevented from entering the air gap 321a during film formation.

On the lower surface of the BL-LP groove portion 321, a part of the metal oxide layer 50a in the upper electrode 50 and a part of the portion 313 in the insulating layer 63 are exposed.

### Manufacturing Method for Semiconductor Device

Hereinafter, a manufacturing method for a semiconductor device 30 according to a first example of a second embodiment will be described as an example of a manufacturing method for a semiconductor device according to the second embodiment.

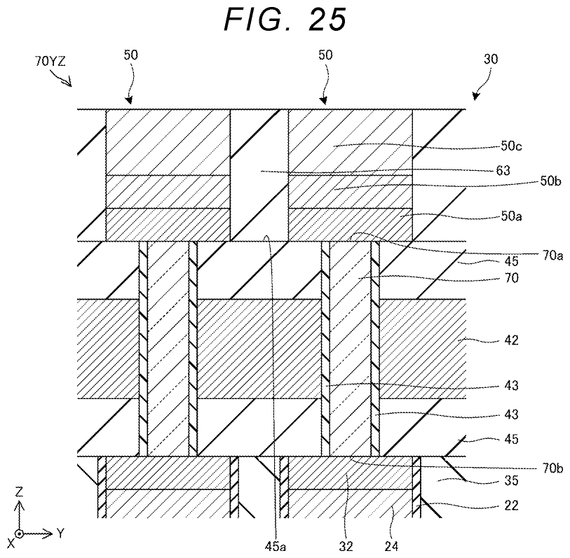

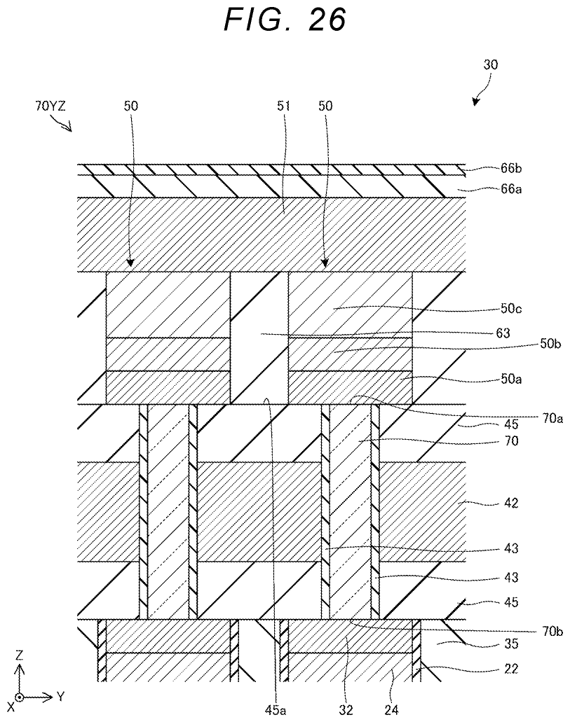

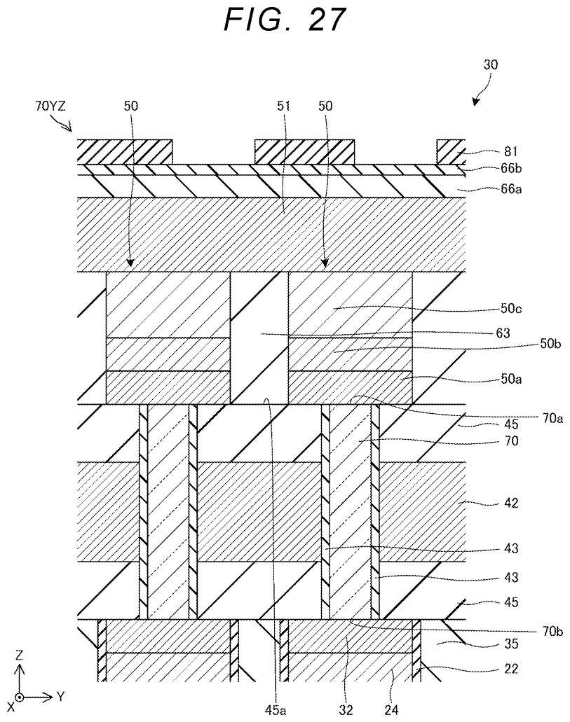

First, as shown in FIG. 25, the upper electrode 50 and the insulating layer 63 are formed on the upper side of the main surface 45a of the insulating layer 45. The metal film 50c, that is, the landing pad is exposed on the upper side of the upper electrode 50.

Next, as shown in FIG. 26, the conductive layer 51 is formed on the surface of the upper electrode 50 and the insulating layer 63 on the upper side. Then, the insulating layers 66a and 66b are formed in this order on the surface of the conductive layer 51 on the upper side.

Next, as shown in FIG. 27, a hard mask layer 81 for forming the bit line BL is formed on the surface of the insulating layer 66b on the upper side. The hard mask layers 81 extend in the X-axis direction and are provided in two or more. Two or more hard mask layers 81 are repeatedly provided in the Y-axis direction. The gap between the two continuous hard mask layers 81 is exposed.

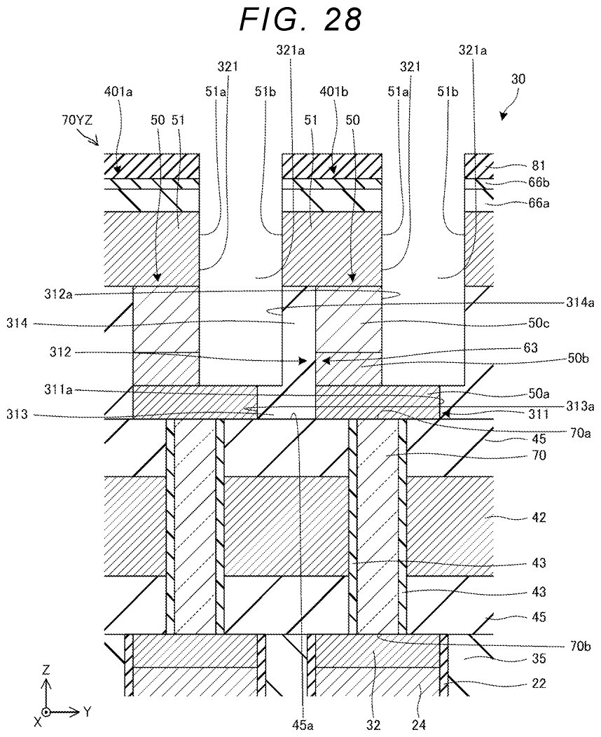

Next, as shown in FIG. 28, the semiconductor device 30 is etched to form the BL-LP groove portion 321 in the portion exposed between the hard mask layers 81. Accordingly, a part of the upper electrode 50 is removed to form the portions 311 and 312. A part of the insulating layer 63 is removed to form the portions 313 and 314.

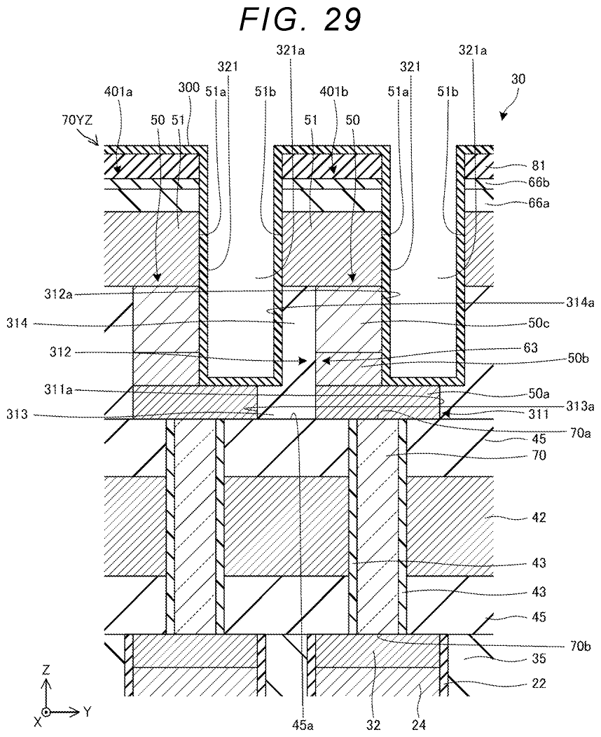

Next, as shown in FIG. 29, a liner film 300 is formed on the surface of the hard mask layer 81 on the upper side and the inner surface of the BL-LP groove portion 321 by a thermal chemical vapor deposition (CVD) method or a plasma-enhanced (PE)-CVD method.

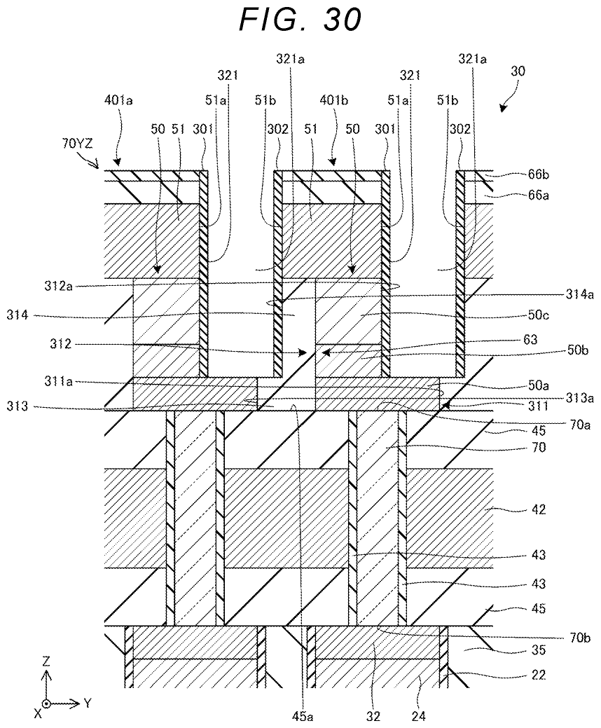

Next, as shown in FIG. 30, the semiconductor device 30 is etched to remove a part of the hard mask layer 81 and a part of the liner film 300. As a result, the liner films 301 and 302 are formed, and a part of the metal oxide layer 50a in the upper electrode 50 and a part of the portion 313 in the insulating layer 63 are exposed at the bottom of the BL-LP groove portion 321.

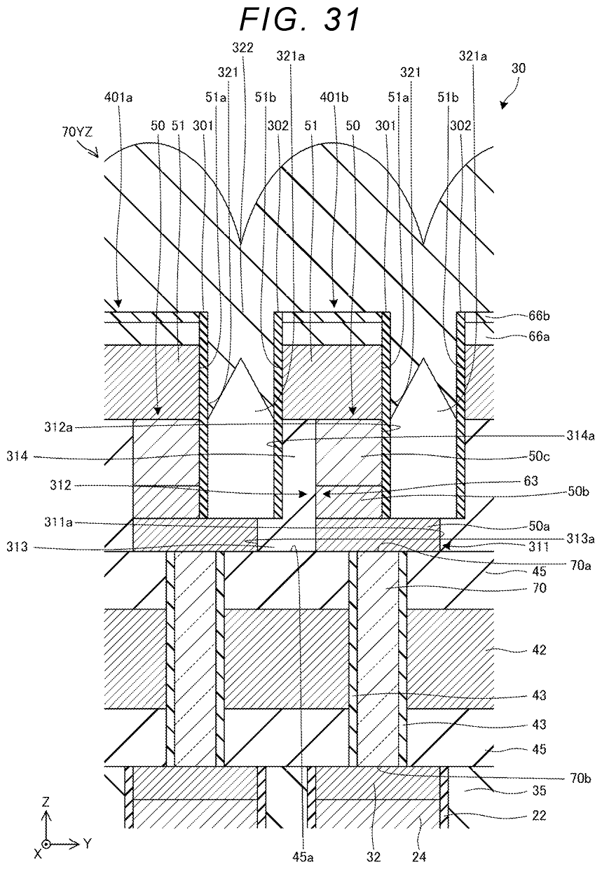

Next, as shown in FIG. 31, the insulating layer 322 is formed on the upper side of the semiconductor device 30 by the PE-CVD method, the low-pressure (LP)-CVD method, or film formation by coating. Accordingly, the upper side of the BL-LP groove portion 321 is blocked by the insulating layer 322, and the gap between the liner film 301 of the group 401a and the liner film 302 of the group 401b is formed as the air gap 321a.

Next, as shown in FIG. 24, the semiconductor device 30 of the first example of the second embodiment is completed as the upper side of the insulating layer 322 is subjected to the chemical mechanical polishing.

### Effect

In order to improve the electrical characteristics of the field effect transistor 40, after the field effect transistor 40 is formed, a heat treatment may be performed under the oxygen reflux to supply oxygen to the oxide semiconductor layer 70 through the metal oxide layer 50a.

When the liner films 301 and 302 are not formed, the metal film 50c containing tungsten and the conductive layer 51 may be abnormally oxidized. In addition, at this time, the metal film 50c and the conductive layer 51 may expand, and the semiconductor device 30 may be mechanically deformed.

On the other hand, in the present embodiment, as shown in FIG. 24, the metal film 50c and the conductive layer 51 are covered with the liner films 301 and 302 having a function of reducing the permeation of oxygen so that the metal film 50c and the conductive layer 51 are not exposed to oxygen and do not react with oxygen.

As a result, the opportunity for the metal film 50c and the conductive layer 51 to come into contact with oxygen can be reduced, and thus abnormal oxidation of the metal film 50c and the conductive layer 51 can be reduced. In addition, the expansion of the metal film 50c and the conductive layer 51 can be reduced, and thus the mechanical deformation of the semiconductor device 30 can be reduced. Therefore, a high-quality semiconductor device 30 can be manufactured.

Hereinafter, a second example of the semiconductor device 30 according to the second embodiment (hereinafter, may be referred to as the second example of the second embodiment) will be described.

### Second Example of Second Embodiment

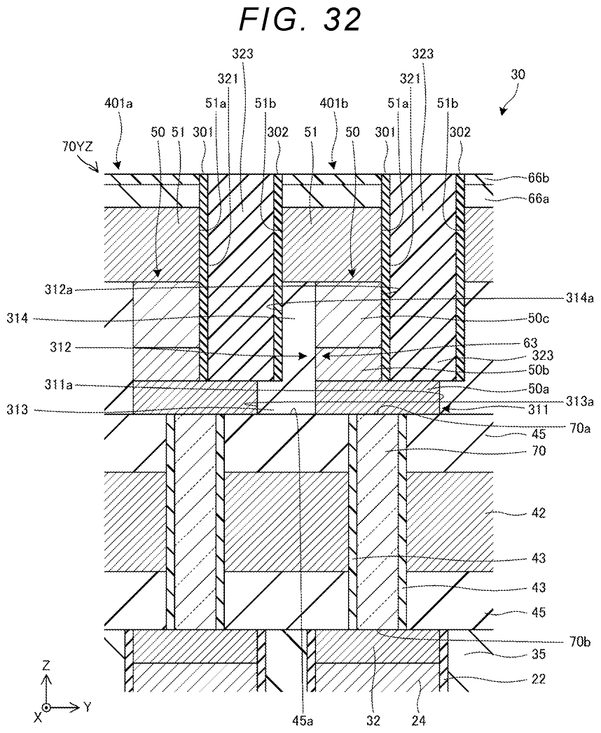

As shown in FIG. 32, the semiconductor device 30 of the second example of the second embodiment is different from the semiconductor device 30 of the first example of the second embodiment shown in FIG. 24 in that the air gap 321a is not formed inside the BL-LP groove portion 321.

The insulating layer 323 (an example of a “fourth insulating layer”) is provided between the group 401a and the group 401b. Specifically, the inside of the BL-LP groove portion 321 is filled with the insulating layer 323. The insulating layer 323 is formed of an oxygen-permeable insulator such as silicon oxide. The capability of the insulating layer 323 to cause oxygen to permeate is greater than the capability of the liner films 301 and 302 to cause oxygen to permeate.

### Manufacturing Method for Semiconductor Device 30 of Second Example of Second Embodiment

In the manufacturing method for the semiconductor device 30 of the second example of the second embodiment, instead of forming the insulating layer 322 on the upper side of the semiconductor device 30 (refer to FIG. 31), the insulating layer 323 is deposited inside the BL-LP groove portion 321 by the PE-CVD method or the LP-CVD method.

Hereinafter, a third example of the semiconductor device 30 according to the second embodiment (hereinafter, may be referred to as the third example of the second embodiment) will be described.

### Third Example of Second Embodiment

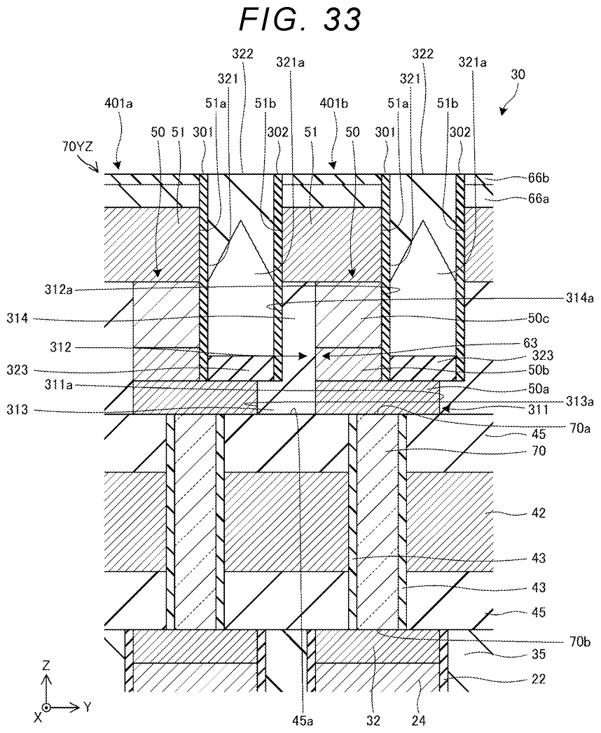

As shown in FIG. 33, the semiconductor device 30 of the third example of the second embodiment is different from the semiconductor device 30 of the first example of the second embodiment shown in FIG. 24 in that the insulating layer 323 is further formed inside the BL-LP groove portion 321 while leaving the air gap 321a.

The insulating layer 323 (an example of a “fourth insulating layer”) is provided on the lower side of the air gap 321a. Specifically, the insulating layer 323 is in contact with the liner films 301 and 302, a part of the metal oxide layer 50a in the upper electrode 50, and a part of the portion 313 in the insulating layer 63, at the bottom of the BL-LP groove portion 321 between the group 401a and the group 401b.

### Manufacturing Method for Semiconductor Device 30 of Third Example of Second Embodiment

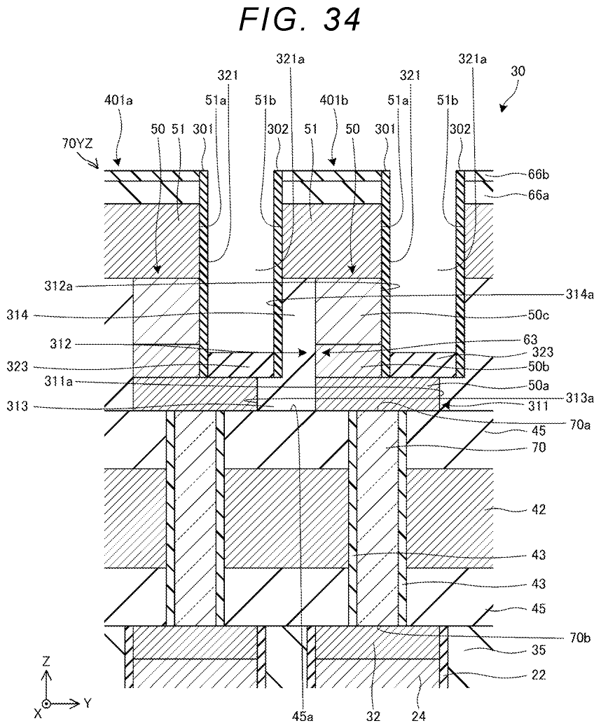

As shown in FIG. 30, after the hard mask layer 81 and a part of the liner film 300 are removed by etching the semiconductor device 30, the insulating layer 323 is formed on the bottom of the BL-LP groove portion 321 by the PE-CVD method or the LP-CVD method as shown in FIG. 34.

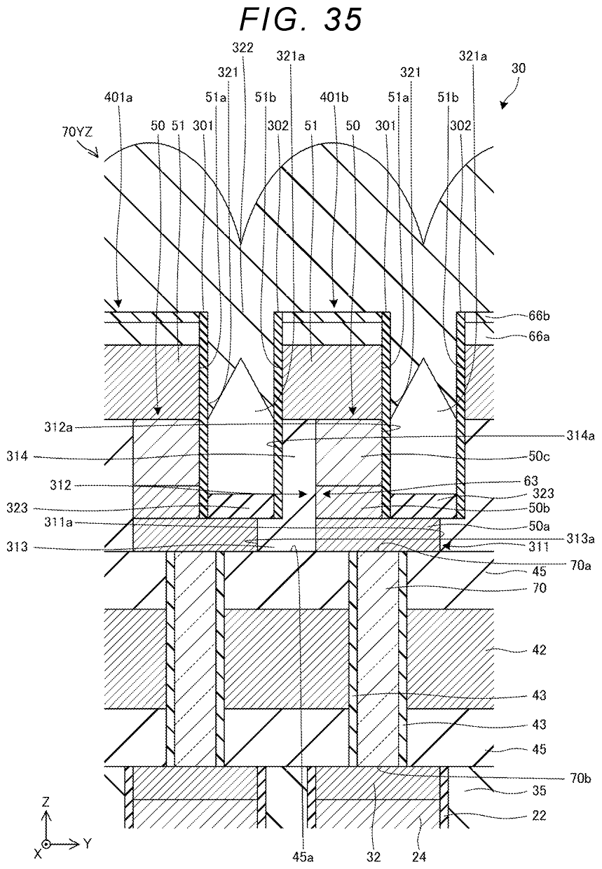

Next, as shown in FIG. 35, the insulating layer 322 is formed on the upper side of the semiconductor device 30 by the PE-CVD method, the LP-CVD method, or film formation by coating. Accordingly, the upper side of the BL-LP groove portion 321 is blocked by the insulating layer 322, and the space surrounded by the liner film 301 of the group 401a, the liner film 302 of the group 401b, the insulating layer 322, and the insulating layer 323 is formed as the air gap 321a.

Next, as shown in FIG. 33, the semiconductor device 30 of the third example of the second embodiment is completed as the upper side of the insulating layer 322 is subjected to the chemical mechanical polishing.

Hereinafter, a fourth example of the semiconductor device 30 according to the second embodiment (hereinafter, may be referred to as the fourth example of the second embodiment) will be described.

### Fourth Example of Second Embodiment

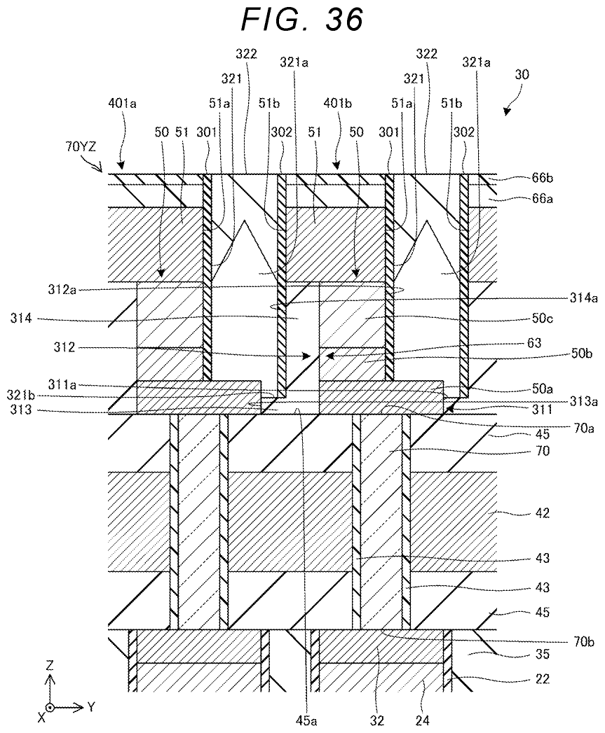

As shown in FIG. 36, the semiconductor device 30 of the fourth example of the second embodiment is different from the semiconductor device 30 of the first example of the second embodiment shown in FIG. 24 in that the entire side surface 311a of the portion 311 in the group 401a and the entire side surface 313a of the portion 313 in the group 401b are not in contact with each other.

In the semiconductor device 30 of the fourth example of the second embodiment, a part on the lower side of the side surface 311a of the portion 311 in the group 401a and the entire side surface 313a of the portion 313 in the group 401b are in contact with each other. Accordingly, the recessed portion 321b is formed between the upper side of the portion 311 in the upper electrode 50 and the lower side of the portion 314 of the insulating layer 63.

By setting the process condition in which the etching rate with respect to the insulating layer 63 is higher than the etching rate with respect to the metal film 50c, the semiconductor device 30 of the fourth example of the second embodiment can be easily manufactured.

Hereinafter, a fifth example of the semiconductor device 30 according to the second embodiment (hereinafter, may be referred to as the fifth example of the second embodiment) will be described.

### Fifth Example of Second Embodiment

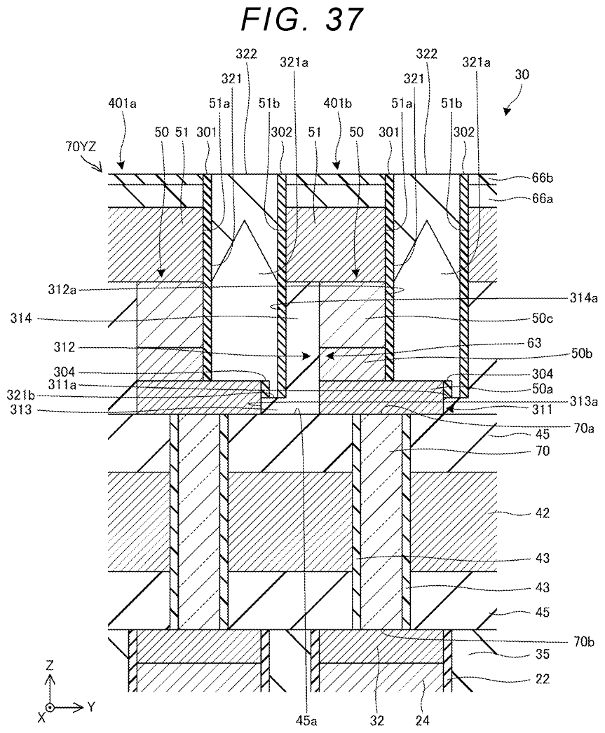

As shown in FIG. 37, the semiconductor device 30 of the fifth example of the second embodiment is different from the semiconductor device 30 of the fourth example of the second embodiment shown in FIG. 36 in that the liner film 304 is provided on the side surface of the recessed portion 321b in the Y-axis−direction.

The semiconductor device 30 of the fifth example of the second embodiment is further provided with a liner film 304 (an example of a “fourth film”) that covers a part of the upper side on the side surface 311a, as compared with the semiconductor device 30 of the fourth example of the second embodiment shown in FIG. 36. The liner film 304 is formed of silicon nitride or aluminum oxide and has a function of reducing the permeation of oxygen.

Hereinafter, a sixth example of the semiconductor device 30 according to the second embodiment (hereinafter, may be referred to as the sixth example of the second embodiment) will be described.

### Sixth Example of Second Embodiment

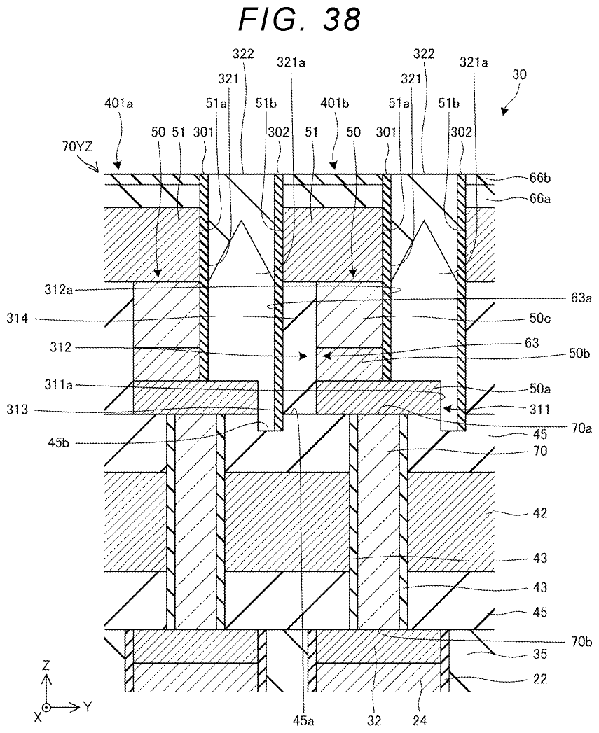

As shown in FIG. 38, the semiconductor device 30 of the sixth example of the second embodiment is different from the semiconductor device 30 of the fourth example of the second embodiment shown in FIG. 36 in that the side surface of the insulating layer 63 in the Y-axis−direction is smooth and the recessed portion 45b reaches the insulating layer 45.

In the semiconductor device 30 of the sixth example of the second embodiment, the upper electrode 50 in the group 401a and the insulating layer 63 in the group 401b are separated from each other.

In the insulating layer 45, a recessed portion 45b that is open on the upper side is formed between the portion 311 of the group 401a and the insulating layer 63 of the group 401b.

The liner film 302 covers a part of the recessed portion 45b in the Y-axis+direction, the side surface 63a of the insulating layer 63 in the Y-axis−direction, the side surface 51b of the conductive layer 51 in the Y-axis−direction, and the side surfaces of the insulating layers 66a and 66b in the Y-axis−direction.

By setting the process condition in which the etching rate with respect to the insulating layer 63 is higher than the etching rate with respect to the metal film 50c, the semiconductor device 30 of the sixth example of the second embodiment can be easily manufactured.

The insulating layer 45 is exposed on a lower surface of the recessed portion 45b and in a part of the recessed portion 45b in the Y-axis−direction. Oxygen can be supplied to the oxide semiconductor layer 70 through the insulating layer 45 exposed in this way. In addition, the side surface of the metal oxide layer 50a in the Y-axis+direction in the portion 311 is also exposed, so that oxygen can be supplied to the oxide semiconductor layer 70 through the side surface.

Hereinafter, a seventh example of the semiconductor device 30 according to the second embodiment (hereinafter, may be referred to as the seventh example of the second embodiment) will be described.

### Seventh Example of Second Embodiment

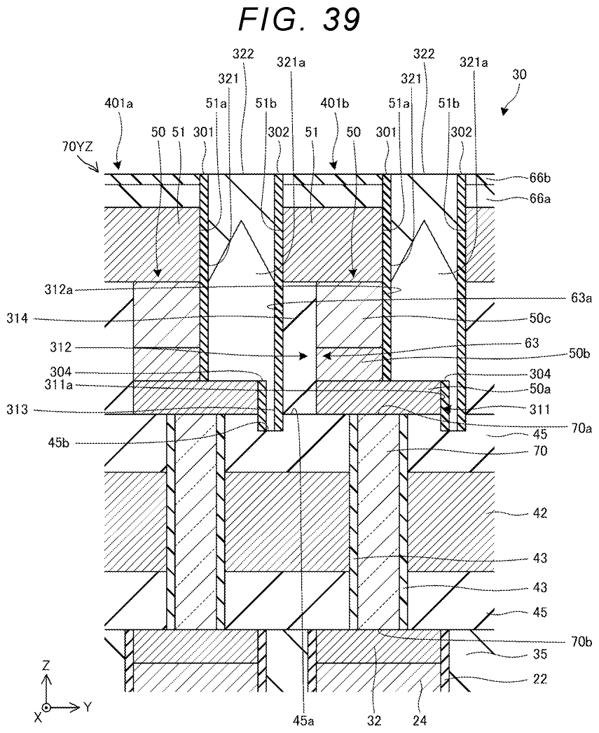

As shown in FIG. 39, the semiconductor device 30 of the seventh example of the second embodiment is different from the semiconductor device 30 of the sixth example of the second embodiment shown in FIG. 38 in that the liner film 304 is provided on the side surface of the recessed portion 45b in the Y-axis−direction.

The semiconductor device 30 of the seventh example of the second embodiment is further provided with a liner film 304 (an example of a “fourth film”) that covers the entire side surface 311a of the portion 311 in the upper electrode 50 and a part of the recessed portion 45b in the Y-axis−direction, as compared with the semiconductor device 30 of the sixth example of the second embodiment shown in FIG. 38.

Hereinafter, an eighth example of the semiconductor device 30 according to the second embodiment (hereinafter, may be referred to as the eighth example of the second embodiment) will be described.

### Eighth Example of Second Embodiment

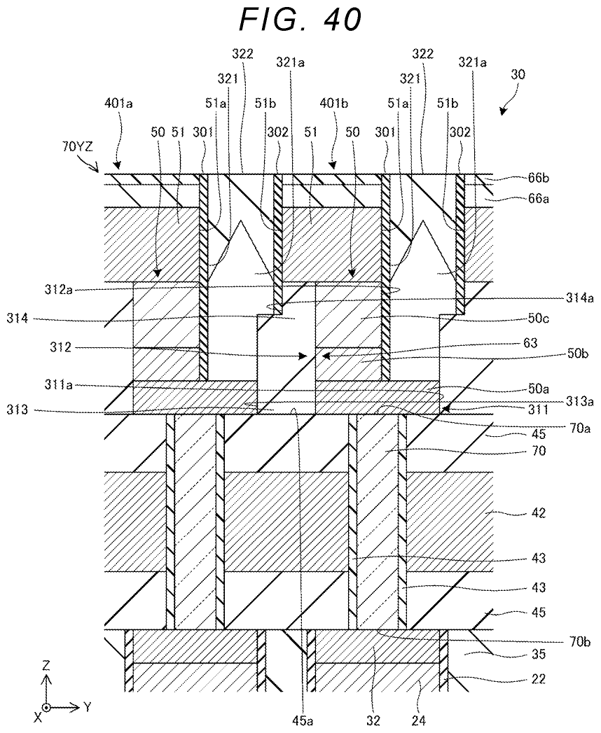

As shown in FIG. 40, the semiconductor device 30 of the eighth example of the second embodiment is different from the semiconductor device 30 of the first example of the second embodiment shown in FIG. 24 in that the entire side surface 311a of the portion 311 in the group 401a and the entire side surface 313a of the portion 313 in the group 401b are not in contact with each other.

In the semiconductor device 30 of the eighth example of the second embodiment, the entire side surface 311a of the portion 311 in the group 401a and a part of the lower side of the side surface 313a of the portion 313 in the group 401b are in contact with each other.

By setting the process condition in which the etching rate with respect to the metal film 50c is higher than the etching rate with respect to the insulating layer 63, the semiconductor device 30 of the eighth example of the second embodiment can be easily manufactured.

Hereinafter, a ninth example of the semiconductor device 30 according to the second embodiment (hereinafter, may be referred to as the ninth example of the second embodiment) will be described.

### Ninth Example of Second Embodiment

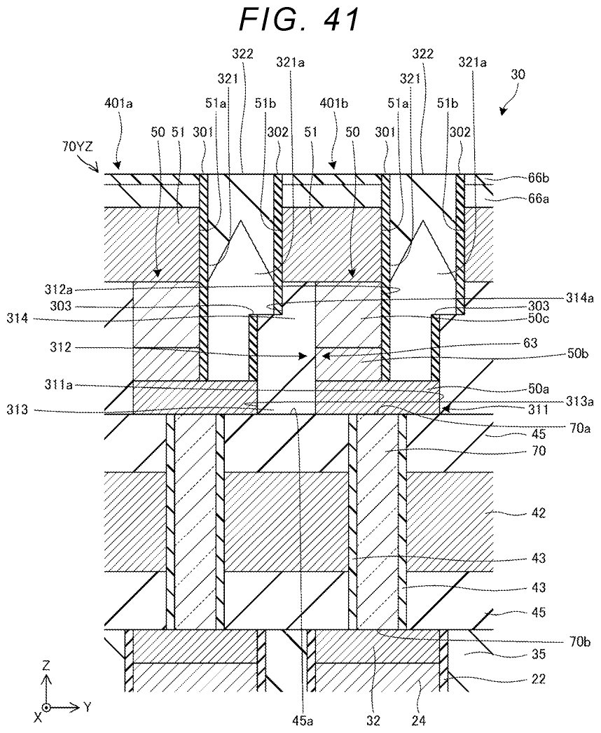

As shown in FIG. 41, the semiconductor device 30 of the ninth example of the second embodiment is different from the semiconductor device 30 of the eighth example of the second embodiment shown in FIG. 40 in that the liner film 303 is provided on the upper side of the side surface 313a of the portion 313 in the insulating layer 63.

The semiconductor device 30 of the ninth example of the second embodiment is further provided with a liner film 303 (an example of a “third film”) that covers a part of the upper side on the side surface 313a, as compared with the semiconductor device 30 of the eighth example of the second embodiment shown in FIG. 40. The liner film 303 is formed of silicon nitride or aluminum oxide and has a function of reducing the permeation of oxygen.

Hereinafter, a tenth example of the semiconductor device 30 according to the second embodiment (hereinafter, may be referred to as the tenth example of the second embodiment) will be described.

### Tenth Example of Second Embodiment

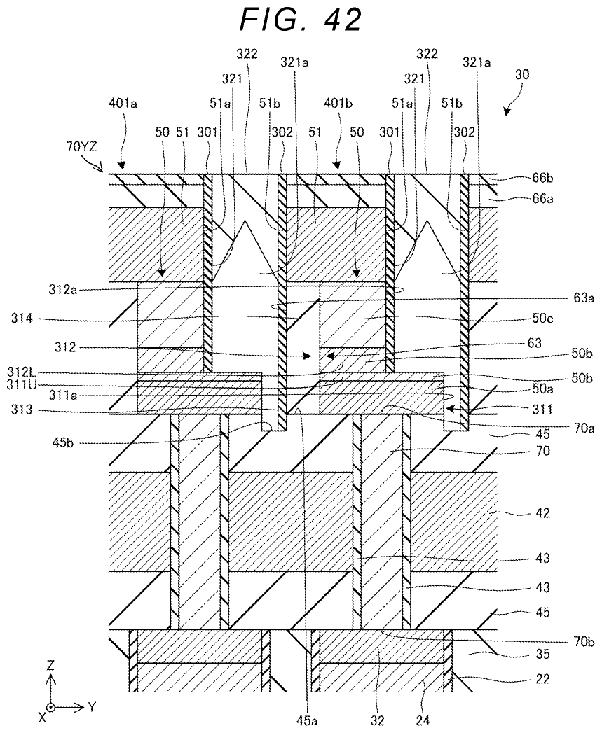

As shown in FIG. 42, the semiconductor device 30 of the tenth example of the second embodiment is different from the semiconductor device 30 of the sixth example of the second embodiment shown in FIG. 38 in that the barrier metal layer 50b in the upper electrode 50 is provided over the portions 311 and 312.

In the semiconductor device 30 of the tenth example of the second embodiment, the barrier metal layer 50b is provided over a portion 312L that is a part of the portion 312 and is located on the lower side of the metal film 50c, and over a portion 311U that is a part of the portion 311 and is located on the upper side with respect to the metal oxide layer 50a.

A part of the surface of the barrier metal layer 50b on the upper side in the Y-axis−direction and the side surface of the barrier metal layer 50b in the Y-axis−direction in the portion 311U are exposed.

Although the surface of the metal oxide layer 50a on the upper side in the portion 311 is covered with the barrier metal layer 50b, the side surface of the metal oxide layer 50a in the Y-axis+direction in the portion 311 is exposed. In addition, the insulating layer 45 is exposed on a lower surface of the recessed portion 45b and in a part of the recessed portion 45b in the Y-axis−direction. Oxygen can be supplied to the oxide semiconductor layer 70 through the side surface of the metal oxide layer 50a in the Y-axis+direction and the insulating layer 45 that are exposed in this way.

Hereinafter, an eleventh example of a semiconductor device 30 according to a second embodiment (hereinafter, may be referred to as the eleventh example of the second embodiment) will be described.

### Eleventh Example of Second Embodiment

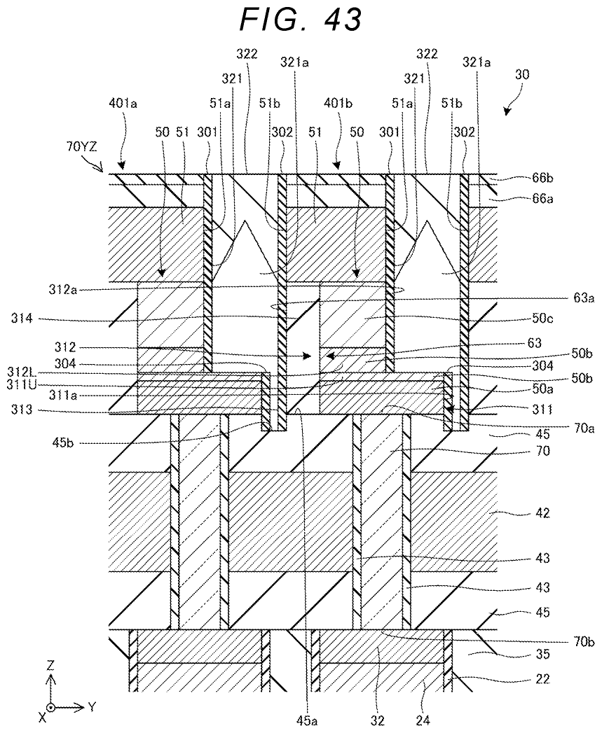

As shown in FIG. 43, the semiconductor device 30 of the eleventh example of the second embodiment is different from the semiconductor device 30 of the seventh example of the second embodiment shown in FIG. 39 in that the barrier metal layer 50b in the upper electrode 50 is provided over the portions 311 and 312.

In the semiconductor device 30 of the eleventh example of the second embodiment, the barrier metal layer 50b is provided over a portion 312L that is a part of the portion 312 and is located on the lower side of the metal film 50c, and over a portion 311U that is a part of the portion 311 and is located on the upper side with respect to the metal oxide layer 50a.

A part of the surface of the barrier metal layer 50b on the upper side in the Y-axis−direction in the portion 311U is exposed. The side surface of the barrier metal layer 50b in the Y-axis−direction in the portion 311U is covered with the liner film 304.

The surface of the metal oxide layer 50a on the upper side in the portion 311 is covered with the barrier metal layer 50b in the portion 311U, and the surface of the metal oxide layer 50a in the Y-axis+direction in the portion 311 is covered with the liner film 304. Therefore, it is difficult to supply oxygen to the oxide semiconductor layer 70 through the metal oxide layer 50a.

On the other hand, the insulating layer 45 is exposed on the lower surface of the recessed portion 45b. Oxygen can be supplied to the oxide semiconductor layer 70 through the insulating layer 45 exposed in this way.

In the semiconductor devices 30 of the fourth example to the eleventh example of the second embodiment, the configuration in which the air gap 321a and the insulating layer 322 are provided inside the BL-LP groove portion 321 was described, but the present disclosure is not limited thereto. As shown in FIG. 32, the inside of the BL-LP groove portion 321 may be filled with the insulating layer 323, or as shown in FIG. 33, the insulating layer 323 may be formed on the bottom of the BL-LP groove portion 321.

(a) In the embodiment, the configuration in which the field effect transistor 40 is used for the OS-RAM was described, but the present disclosure is not limited thereto. The field effect transistor 40 may also be applied to a semiconductor device other than OS-RAM.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first insulating layer;
an oxide semiconductor formed in the first insulating layer, extending in a first direction, and having a first end and a second end;
a first electrode including a first metal film that includes a first metal atom, and a first conductive film that is formed between the first metal film and the first end of the oxide semiconductor and includes metal oxide;
a second electrode in contact with the second end of the oxide semiconductor;
at least a pair of gate electrodes that face each other via an insulating film, and are interposed between the first end and the second end of the oxide semiconductor; and
a first structure that is separated from the first electrode in a second direction intersecting the first direction, includes at least the first metal atom, and does not include the metal oxide.

2. The semiconductor device according to claim 1, further comprising:
a second insulating layer surrounding the first structure.

3. The semiconductor device according to claim 1,
wherein an area of the first structure is larger than an area of the first electrode when viewed along the first direction.

4. The semiconductor device according to claim 1,
wherein the first structure is provided with a second metal film having the same composition as the first metal film.

5. The semiconductor device according to claim 4,
wherein the first insulating layer is provided with a first surface continuous with a contact surface between the first end and the first conductive film,
the first metal film has a first thickness, and is provided away from the first surface, and
the second metal film has the first thickness, and is provided in contact with the first surface.

6. The semiconductor device according to claim 4, further comprising:
a signal line in contact with the first metal film, and the first metal film and the second metal film are provided between the semiconductor device and the first insulating layer.

7. The semiconductor device according to claim 1,
wherein a plurality of the oxide semiconductors are two-dimensionally arranged in a first area, and a plurality of the first structures are two-dimensionally arranged in a second area located along an outer edge of the first area, when viewed along the first direction.

8. The semiconductor device according to claim 7, further comprising:
a plurality of dummy electrodes each including a third metal film that includes the first metal atom, and a second conductive film that is formed between the third metal film and the first insulating layer and containing the metal oxide and is provided in the second area,
wherein the plurality of first structures are provided along an outer edge of the second area, when viewed along the first direction.

9. The semiconductor device according to claim 4,
wherein the first structure includes a hole portion overlapped with the second metal film and penetrating the first insulating layer when viewed along the first direction.

10. The semiconductor device according to claim 1,
wherein the metal oxide includes indium and tin.

11. The semiconductor device according to claim 1,
wherein the first direction is perpendicular to the second direction.

12. A semiconductor device comprising:
a first insulating layer;
an oxide semiconductor formed in the first insulating layer, having a first end and a second end, and extending in a first direction;
a first electrode formed in the first direction with respect to the oxide semiconductor, wherein the first electrode includes:
a first portion in contact with the first end of the oxide semiconductor, and including a first side surface in a second direction intersecting the first direction, and
a second portion provided in the first direction with respect to the first portion, and including a second side surface in the second direction;
a second electrode in contact with the second end of the oxide semiconductor;
gate electrodes that face each other via an insulating film, and are interposed between the first end and the second end of the oxide semiconductor; and
a first film,
wherein the first portion of the first electrode includes indium and tin, and is provided with at least a first metal oxide electrode portion provided in a direction opposite to the first direction,
the second portion of the first electrode includes tungsten, and at least a pad provided in the first direction,
the first side surface is located in the second direction with respect to the second side surface in a cross section parallel to a plane defined by the first direction and the second direction, and
the first film covers the second side surface.

13. The semiconductor device according to claim 12,
wherein the second portion of the first electrode further includes a first barrier metal portion containing titanium and nitrogen in a direction opposite to the first direction with respect to the pad.

14. The semiconductor device according to claim 13,
wherein the first barrier metal portion in the second portion and the first metal oxide electrode portion in the first portion are in contact with each other.

15. The semiconductor device according to claim 13,
wherein the first barrier metal portion is provided over a part of the second portion that is located in the direction opposite to the first direction with respect to the pad, and over a part of the first portion that is located in the first direction with respect to the first metal oxide electrode portion.

16. The semiconductor device according to claim 12, further comprising:
a second insulating layer provided in a direction opposite to the second direction with respect to the first electrode; and
a signal line provided in the first direction with respect to the first electrode and the second insulating layer,
wherein the first film further covers a side surface of the signal line in the second direction.

17. The semiconductor device according to claim 16, further comprising:
a second film that covers a side surface of the signal line in the direction opposite to the second direction.

18. The semiconductor device according to claim 17,
wherein the signal line extends in a third direction intersecting the first direction and the second direction,
the gate electrode extends in the second direction,
the semiconductor device comprises:
two or more signal lines repeatedly provided in the second direction;
two or more gate electrodes repeatedly provided in the third direction; and
two or more groups including the first electrode, the oxide semiconductor, the second electrode, the second insulating layer, the first film, and the second film, and provided for each of the signal lines and for each of the gate electrodes, and
the first film provided in a first group, which is the group in the direction opposite to the second direction among continuous two groups, and the second film provided in a second group, which is the group in the second direction among the continuous two groups, face each other.

19. The semiconductor device according to claim 18,
wherein an air gap is provided between the first group and the second group.

20. The semiconductor device according to claim 19, further comprising:
a third insulating layer provided in the first direction with respect to the air gap.

21. The semiconductor device according to claim 19, further comprising:
a fourth insulating layer provided in a direction opposite to the first direction with respect to the air gap.

22. The semiconductor device according to claim 18, further comprising:
a fourth insulating layer provided between the first group and the second group.

23. The semiconductor device according to claim 18,
wherein the second insulating layer includes
a third portion provided with a third side surface in the direction opposite to the second direction, and
a fourth portion provided in the first direction with respect to the third portion and provided with a fourth side surface in the direction opposite to the second direction,
the third side surface is located in the direction opposite to the second direction with respect to the fourth side surface in the cross section, and
the second film further covers the fourth side surface.

24. The semiconductor device according to claim 23,
wherein at least a part of the third side surface of the third portion and at least a part of the first side surface of the first portion are in contact with each other.

25. The semiconductor device according to claim 23,
wherein the entire third side surface of the third portion and the entire first side surface of the first portion are in contact with each other.

26. The semiconductor device according to claim 23,
wherein a part of the third side surface of the third portion in a direction opposite to the first direction and the entire first side surface of the first portion are in contact with each other.

27. The semiconductor device according to claim 26, further comprising:
a third film,
wherein the third film covers a part of the third side surface in the first direction.

28. The semiconductor device according to claim 23,
wherein the entire third side surface of the third portion and a part of the first side surface of the first portion in a direction opposite to the first direction are in contact with each other.

29. The semiconductor device according to claim 28, further comprising:
a fourth film,
wherein the fourth film covers a part of the first side surface in the first direction.

30. The semiconductor device according to claim 18,
wherein the first electrode in the first group and the second insulating layer in the second group are separated from each other, and
the second film further covers a side surface of the second insulating layer in the direction opposite to the second direction.

31. The semiconductor device according to claim 30, further comprising:
a fourth film,
wherein the fourth film covers the first side surface.

32. The semiconductor device according to claim 30,
wherein a recessed portion that is open in the first direction is formed between the first portion of the first group and the second insulating layer of the second group in the first insulating layer, and
the second film further covers a part of the recessed portion in the second direction from the entire side surface of the second insulating layer in the direction opposite to the second direction.

33. The semiconductor device according to claim 31,
wherein a recessed portion that is open in the first direction is formed between the first portion of the first group and the second insulating layer of the second group in the first insulating layer, and
the fourth film further covers a part of the recessed portion in the direction opposite to the second direction.

34. The semiconductor device according to claim 12,
wherein the first film is formed of silicon nitride or aluminum oxide.

35. A semiconductor storage device comprising:
the semiconductor device according to claim 1;
a first capacitor electrode that is connected to the first electrode or the second electrode;
a second capacitor electrode that faces the first capacitor electrode; and
a dielectric film that is provided between the first capacitor electrode and the second capacitor electrode.
